(19) United States
(12) Patent Application Publication
(10) Pub. No.: US 2026/0130028 A1
(43) Pub. Date: May 7, 2026

(54) MICRO LIGHT EMITTING DISPLAY DEVICE AND METHOD OF MANUFACTURING THE SAME

(71) Applicant: SAMSUNG ELECTRONICS CO.,LTD., Suwon-si (KR)

(72) Inventors: Junhee CHOI, Suwon-si (KR); Kiho KONG, Suwon-si (KR); Nakhyun KIM, Suwon-si (KR); Sunil KIM, Suwon-si (KR)

(73) Assignee: SAMSUNG ELECTRONICS CO.,LTD., Suwon-si (KR)

(21) Appl. No.: 19/375,862

(22) Filed: Oct. 31, 2025

(30) Foreign Application Priority Data
Nov. 1, 2024 (KR) 10-2024-0153787

(51) Int. Cl. H10H 29/39; H10H 29/01; H10H 29/855

(52) U.S. Cl. CPC H10H 29/39; H10H 29/012; H10H 29/0363; H10H 29/855

(57) ABSTRACT

A micro-light emitting display device includes a backplane substrate including at least one driving device, a bonding layer on the backplane substrate, a first bonding pillar extending in a first direction that is perpendicular to an upper surface of the backplane substrate, and a first light emitting device and a second light emitting device spaced apart from each other in a second direction intersecting the first direction, where the first light emitting device is on the bonding layer and the second light emitting device is on the first bonding pillar such that the second light emitting device is positioned at a height in the first direction that is different from a height at which the first light emitting device is positioned in the first direction.

### CROSS-REFERENCE TO RELATED APPLICATION

This application is based on and claims priority to Korean Patent Application No. 10-2024-0153787, filed on November 01, 2024, in the Korean Intellectual Property Office, the disclosure of which is incorporated by reference herein in its entirety.

### BACKGROUND

### 1. Field

The disclosure relates to a micro light emitting display device for displaying a color image and a method of manufacturing the same.

### 2. Description of Related Art

Liquid crystal displays (LCD) and organic light emitting diode (LED) (OLED) displays are widely used as display devices. In addition, a technology for manufacturing high-resolution display devices using micro LEDs has recently been in the spotlight. Micro LEDs have the advantages of low-power consumption and environmental friendliness. Due to these advantages, the industrial demands for micro LEDS are increasing.

LED displays that directly use micro LEDs as pixels have been developed and commercialized.

An LED display pixel may be designed in various ways, and recently, various technologies for vertically stacking micro LEDs emitting red light (R), which are abbreviated as R-LEDs), a micro LEDs emitting green light (G), which are abbreviated as G-LEDs), and micro LEDs emitting blue light (B), which are abbreviated as B-LEDs), have been introduced. However, vertical stacking of micro LEDs has not yet yielded satisfactory results in terms of efficiency or bonding.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is a micro light emitting display device and a method of manufacturing a micro light emitting display device.

Additional aspects will be set forth in part in the description which follows and, in part, will be apparent from the description, or may be learned by practice of the presented embodiments of the disclosure.

According to an aspect of the disclosure, a micro-light emitting display device may include a backplane substrate including at least one driving device, a bonding layer on the backplane substrate, a first bonding pillar extending in a first direction that is perpendicular to an upper surface of the backplane substrate, and a first light emitting device and a second light emitting device spaced apart from each other in a second direction intersecting the first direction, where the first light emitting device is on the bonding layer and the second light emitting device is on the first bonding pillar such that the second light emitting device is positioned at a height in the first direction that is different from a height at which the first light emitting device is positioned in the first direction.

The first bonding pillar may be between the bonding layer and the second light emitting device and may protrude from the bonding layer toward the second light emitting device.

The first bonding pillar may include a polymer-based material.

The first bonding pillar may include a material that is the same as a material of the bonding layer.

The first light emitting device may include a first electrode, a first semiconductor layer, a first active layer configured to emit light of a first wavelength, a second semiconductor layer, and a second electrode, which are stacked in order in the first direction, the second light emitting device may include a third electrode, a third semiconductor layer, a second active layer configured to emit light having a second wavelength different from the first wavelength, a fourth semiconductor layer, and a fourth electrode, which are stacked in order in the first direction, in the second direction, the first electrode may have a width that is greater than a width of the first semiconductor layer, the first electrode may include a first open surface extending from a side of the first light emitting device and connected to at least one driving device of the at least one driving device, in the second direction, the third electrode may have a width that is greater than a width of the third semiconductor layer, and the third electrode may include a second open surface extending from a side of the second light emitting device and may be connected to at least one driving device of the at least one driving device.

In the second direction, the first bonding pillar may have a width that is greater than a width of the second active layer of the second light emitting device.

In the second direction, the first bonding pillar may have a width that is substantially the same as the width of the third electrode.

The display device may include a first conductive layer configured to connect the at least one driving device to at least one of the first open surface and the second open surface.

The display device may include a planarization layer covering the first conductive layer, where a surface of the first light emitting device and a surface of the second light emitting device may be exposed through the planarization layer.

The display device may include a second conductive layer contacting the surface of the first light emitting device and the surface of the second light emitting device which are exposed through the planarization layer.

The display device may include a first lens above the first light emitting device and having a convex upper portion, and a second lens above the second light emitting device and having a convex upper portion.

The planarization layer may include a first hole exposing the surface of the first light emitting device, and the micro light emitting display device may include a reflective layer on a side surface of the first hole.

A surface of the first light emitting device and a surface of the second light emitting device each may include an uneven structure.

The display device may include a second bonding pillar extending in the first direction to a height that is different from a height of the first bonding pillar, a third light emitting device on the second bonding pillar and spaced apart from the second light emitting device in the second direction such that the third light emitting device is positioned at a height in the first direction that is different from the height of the first light emitting device in the first direction and the height of the second light emitting device in the first direction.

According to an aspect of the disclosure, a method of manufacturing a micro light emitting display device may include providing a first bonding layer on a backplane substrate, forming a first light emitting device on the first bonding layer, providing a second bonding layer that covers the first light emitting device and the first bonding layer, forming a second light emitting device on the second bonding layer, and etching the second bonding layer such that a first bonding pillar is formed below the second light emitting device in a first direction that is perpendicular to an upper surface of the backplane substrate.

The forming of the first light emitting device may include forming a first epitaxial structure by providing a second epitaxial semiconductor layer, a first epitaxial active layer, a first epitaxial semiconductor layer, and a first epitaxial electrode in order on a first epitaxial substrate, inverting the first epitaxial structure and providing the inverted first epitaxial structure on the first bonding layer, removing the first epitaxial substrate of the first epitaxial structure, forming a second epitaxial electrode on the first epitaxial structure, and etching the first epitaxial structure such that a width of the first light emitting device is on the upper surface of the first bonding layer, and the forming of the second light emitting device may include forming a second epitaxial structure by providing a third epitaxial electrode on the second bonding layer, a third epitaxial semiconductor layer on the third epitaxial electrode, a second epitaxial active layer on the third epitaxial semiconductor layer, and a fourth epitaxial semiconductor layer on the second epitaxial active layer, forming a fourth epitaxial electrode on the second epitaxial structure, and etching the second epitaxial structure such that a width of the second light emitting device is less than a width of the second bonding layer.

The backplane substrate may include at least one driving device, the first light emitting device may include a first electrode, a first semiconductor layer, a first active layer configured to emit light of a first wavelength, a second semiconductor layer, and a second electrode, which are stacked in order on the first bonding layer, the second light emitting device may include a third electrode, a third semiconductor layer, a second active layer configured to emit light having a second wavelength different from the first wavelength, a fourth semiconductor layer, and a fourth electrode, which are stacked in order on the second bonding layer, the first electrode may have a width that is greater than a width of the first semiconductor layer and may include a first open surface extending from a side of the first light emitting device, and the third electrode may have a width that is greater than a width of the third semiconductor layer and may include a second open surface extending from a side of the second light emitting device, and the method may include forming a first conductive layer respectively connecting driving devices of the at least one driving device to the first electrode and the second electrode.

The method may include forming a planarization layer covering the first conductive layer, forming a first hole in the planarization layer exposing the second electrode of the first light emitting device, forming a second hole in the planarization layer exposing the fourth electrode of the second light emitting device, and forming a second conductive layer that contacts the second electrode exposed through the first hole and the fourth electrode exposed through the second hole.

The method may include forming a first lens filling the first hole and having a shape with a convex upper portion, and forming a second lens filling the second hole and having a shape with a convex upper portion.

The method may include, prior to forming the first lens, forming a reflective layer on a side surface of the first hole.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a diagram illustrating an example of a micro light emitting display device according to one or more embodiments;

FIG. 2 is a plan view illustrating an example of a micro light emitting display device according to one or more embodiments;

FIG. 3 is a diagram illustrating another example of a micro light emitting display device according to one or more embodiments;

FIG. 4 is a diagram illustrating an example in which a third light emitting device is further provided in the micro light emitting display device shown in FIG. 1 according to one or more embodiments;

FIG. 5 is a diagram illustrating an electrode connection structure of the micro light emitting display device of FIG. 4 according to one or more embodiments;

FIG. 6 is a diagram illustrating another example of a micro light emitting display device according to one or more embodiments;

FIG. 7 is a diagram illustrating another example of a micro light emitting display device according to one or more embodiments;

FIG. 8 is a diagram illustrating an example of a pixel structure of a micro light emitting display device according to one or more embodiments;

FIG. 9 is a diagram illustrating another example of a pixel structure of a micro light emitting display device according to one or more embodiments;

FIG. 10 is a flowchart illustrating a method of manufacturing a micro light emitting display device according to one or more embodiments;

FIGS. 11A to 11G are diagrams illustrating a method of manufacturing a micro light emitting display device according to one or more embodiments;

FIGS. 12A to 12D are diagrams illustrating an operation of arranging a first light emitting device on a bonding layer according to one or more embodiments;

FIGS. 13A and 13B are diagrams illustrating an operation of arranging a second light emitting device on a first bonding layer according to one or more embodiments;

FIGS. 14A and 14B are diagrams illustrating an operation of arranging a third light emitting device on a second bonding layer according to one or more embodiments;

FIGS. 15A to 15H are diagrams illustrating a method of forming an electrode connection structure of a micro light emitting display device according to one or more embodiments;

FIG. 16 is a block diagram of an electronic device including a display device, according to one or more embodiments;

FIG. 17 is a diagram illustrating an example of applying an electronic device to a mobile device according to one or more embodiments;

FIG. 18 is a diagram illustrating an example of applying a display device to a vehicle according to one or more embodiments;

FIG. 19 is a diagram illustrating an example of applying a display device to augmented reality glasses or virtual reality glasses according to one or more embodiments;

FIG. 20 is a diagram illustrating an example of applying a display device to a large signage according to one or more embodiments; and

FIG. 21 is a diagram illustrating an example of applying a display device to a wearable display according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

Hereinafter, various embodiments will be described in detail with reference to the accompanying drawings. In the following drawings, the same reference numerals refer to the same components, and the size of each component in the drawings may be exaggerated for clarity and convenience of description. The terms first, second, etc. may be used to describe various components, but the components should not be limited by the terms. The terms are used only for the purpose of distinguishing one component from other components.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The expression of the singular includes the expression of the plural, unless the context clearly indicates otherwise. The use of the terms “a” and “an” and “the” and similar referents are to be construed to cover both the singular and the plural. The steps of all methods described herein can be performed in any suitable order unless otherwise indicated herein or otherwise clearly contradicted by context, and are not limited to the described order. In addition, when a part “contains” a component, this means that it may contain other components, rather than excluding other components, unless otherwise stated. In addition, the size or thickness of each component in the drawing may be exaggerated for clarity of explanation. Additionally, when a predetermined material layer is described as being on a substrate or another layer, the material layer may exist in direct contact with the substrate or the other layer, or another third layer may exist in between. In addition, since the materials constituting each layer in the embodiments below are only examples, other materials may be used.

The use of any and all examples, or exemplary language (e.g., “such as”) provided herein, is intended merely to better illuminate the disclosure and does not pose a limitation on the scope of the disclosure unless otherwise claimed.

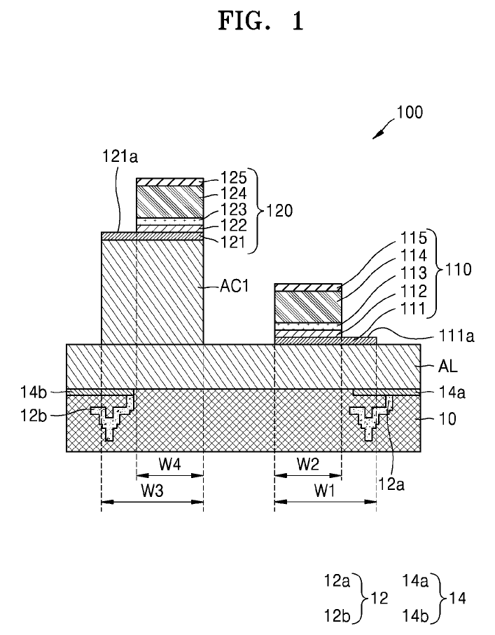

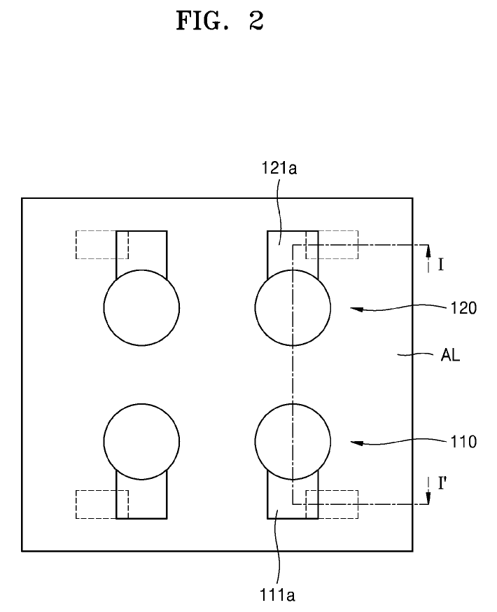

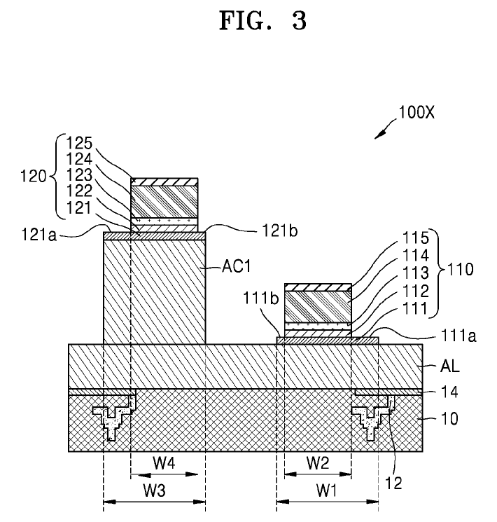

FIG. 1 is a diagram illustrating an example of a micro light emitting display device 100 according to one or more embodiments. FIG. 2 is a plan view schematically illustrating an example of the micro light emitting display device 100 according to one or more embodiments. FIG. 3 is a diagram illustrating another example of a micro light emitting display device 100X according to one or more embodiments. FIG. 1 is a cross-sectional view of the micro light emitting display device 100 taken along line I-I’ of FIG. 2.

Referring to FIGS. 1 and 2, the micro light emitting display device 100 may include a backplane substrate 10 including at least one driving device 12 (e.g., driving devices 12a and 12b), a first light emitting device 110 and a second light emitting device 120 spaced apart from each other and above the backplane substrate 10. That is, the first light emitting device 110 and the second light emitting device 120 may be provided above the backplane substrate 10 in a first direction (e.g., vertical direction) that is perpendicular to an upper surface of the backplane substrate 10 and may be spaced apart from each other in a second direction that intersects the first direction (e.g., horizontal direction).

The at least one driving device 12 is provided to electrically drive the first light emitting device 110 and the second light emitting device 120, and may include, for example, a transistor, a thin film transistor, or a high electron mobility transistor (HEMT). However, the driving device 12 is not limited thereto, and may further include a resistor, a capacitor, or the like.

The backplane substrate 10 may include electrode pads 14 spaced apart from each other, and the electrode pads 14 may be prepared for ground or connected to one of a plurality of driving devices 12 included in the backplane substrate 10. For example, the electrode pads 14 may be connected to the driving devices 12 provided on the backplane substrate 10 to drive the first light emitting device 110 and the second light emitting device 120, for example, drains of respective transistors.

In one or more embodiments, the at least one driving device 12 may include a first driving device 12a corresponding to the first light emitting device 110, and a second driving device 12b corresponding to the second light emitting device 120. Furthermore, electrode pads 14 may include a first electrode pad 14a corresponding to the first light emitting device 110 and a second electrode pad 14b corresponding to the second light emitting device 120. Further description herein may refer to multiple driving devices as at least one driving device and multiple electrode pads as an electrode pad for ease of description.

A bonding layer AL may be provided between the first light emitting device 110 and the backplane substrate 10. The bonding layer AL may have a thickness in the range of about 0.3 μm to about 5 μm. The bonding layer AL may have a thickness in the range of about 0.2 μm to about 4 μm.

The bonding layer AL is provided to bond an epitaxial structure to be described later to the backplane substrate 10, and may include a polymer material. For example, the bonding layer AL may include at least one of epoxy, polyimide (PI), and benzocyclobutene (BCB). The bonding layer AL is provided to physically couple the epitaxial structure to the backplane substrate 10, and the epitaxial structure may be coupled to the backplane substrate 10 in a simple manner that does not require electrical connection. However, the bonding layer AL is not limited thereto.

The first light emitting device 110 may include a first electrode 111, a first semiconductor layer 112, a first active layer 113 that emits light of a first wavelength, a second semiconductor layer 114, and a second electrode 115, which are stacked in order. In the first light emitting device 110, the first electrode 111, the first semiconductor layer 112, the first active layer 113 emitting light of the first wavelength, the second semiconductor layer 114, and the second electrode 115 may be stacked in order on a portion of a top surface of the bonding layer AL (i.e., the width of the first light emitting device 110 may be less than a total width of the bonding layer AL).

The first semiconductor layer 112 may include a first type semiconductor. For example, the first semiconductor layer 112 may include a p-type semiconductor. Alternatively, the first semiconductor layer 112 may include an n-type semiconductor. The first semiconductor layer 112 may include a group III-V-based p-type semiconductor, for example, p-GaN, p-InGaN, p-AlInGaN, or p-AlGaInP. The first semiconductor layer 112 may have a single-layer structure or a multi-layer structure.

The first active layer 113 may be provided on a top surface of the first semiconductor layer 112. In the first active layer 113, electrons and holes may be combined to generate light. The first active layer 113 may include a material that emits light of a first wavelength, for example, red light. However, the first active layer 113 is not limited thereto. The first active layer 113 may have a multi-quantum well (MQW) structure or a single-quantum well (SQW) structure. The first active layer 113 may include a group III-V-based semiconductor, for example, GaN, InGaN, AlInGaN, or AlGaInP.

The second semiconductor layer 114 may be provided on a top surface of the first active layer 113. The second semiconductor layer 114 may include, for example, an n-type semiconductor. Alternatively, the second semiconductor layer 114 may include a p-type semiconductor. The second semiconductor layer 114 may include a group III-V-based n-type semiconductor, for example, n-GaN, n-InGaN, n-AlInGaN, or n-AlGaInP. The second semiconductor layer 114 may have a single-layer structure or a multi-layer structure.

A width W1 of the first electrode 111 may be greater than a width W2 of the first semiconductor layer 112. In addition, the first electrode 111 may include a first open surface 111a extending from a side of the first light emitting device 110. The first open surface 111a may be electrically connected to at least one driving device 12 (e.g., driving device 12a). When the first open surface 111a and the at least one driving device 12 are connected to each other, they may be directly connected to each other or connected to each other through another medium. The first open surface 111a may be provided on only one side of the first electrode 111 as shown in FIG. 1, and first open surfaces 111a and 111b may be provided on both sides of the first electrode 111 as shown in the device 100X in FIG. 3. The first semiconductor layer 112, the first active layer 113, the second semiconductor layer 114, and the second electrode 115 may have substantially the same widths.

The first light emitting device 110 may have a structure in which a voltage is applied across the first electrode 111 and the second electrode 115 to activate the first active layer 113.

The first electrode 111 may include a reflective material to reflect light emitted downward from the first active layer 113. The first electrode 111 may include, for example, Ag, Au, Al, Cr, or Ni, or an alloy thereof. However, the first electrode 111 is not limited thereto.

The second electrode 115 may be formed as a transparent electrode so that light emitted from the first active layer 113 may be emitted. The second electrode 115 may include, for example, indium tin oxide (ITO), zinc oxide (ZnO), indium zinc oxide (IZO), indium gallium zinc oxide (IGZO), or the like. However, the second electrode 115 is not limited thereto.

The second light emitting device 120 may include a third electrode 121, a third semiconductor layer 122, a second active layer 123 that emits light of a second wavelength, a fourth semiconductor layer 124, and a fourth electrode 125, which are stacked in order in a direction perpendicular to the backplane substrate 10. ”In order” may refer to the order of the layers and does not limit the presence of other layers between the layers.

The third semiconductor layer 122 may include a first type semiconductor. For example, the third semiconductor layer 122 may include a p-type semiconductor. Alternatively, the third semiconductor layer 122 may include an n-type semiconductor. The third semiconductor layer 122 may include a group III-V-based p-type semiconductor, for example, p-GaN, p-InGaN, p-AlInGaN, or p-AlGaInP. The third semiconductor layer 122 may have a single-layer structure or a multi-layer structure. The third semiconductor layer 122 may include the same material as the first semiconductor layer 112. Alternatively, the third semiconductor layer 122 may include a material different from that of the first semiconductor layer 112.

The second active layer 123 may be provided on a top surface of the third semiconductor layer 122. The second active layer 123 may generate light of a second wavelength, and the second wavelength may be different from the first wavelength. The second wavelength light may have, for example, a green light wavelength. However, the second active layer 123 is not limited thereto.

The second active layer 123 may have a MQW structure or a SQW structure. The second active layer 123 may include a group III-V-based semiconductor, for example, GaN, InGaN, AlInGaN, or AlGaInP. The second active layer 123 may include a material different from that of the first active layer 113. Here, the different materials may include not only cases in which constituent elements are different, but also cases in which constituent elements are the same and composition ratios are different.

The fourth semiconductor layer 124 may be provided on a top surface of the second active layer 123. The fourth semiconductor layer 124 may include, for example, an n-type semiconductor. Alternatively, the fourth semiconductor layer 124 may include a p-type semiconductor. The fourth semiconductor layer 124 may include a group III-V-based n-type semiconductor, for example, n-GaN, n-InGaN, n-AlInGaN, or n-AlGaInP. The fourth semiconductor layer 124 may have a single-layer structure or a multi-layer structure.

A width W3 of the third electrode 121 may be greater than a width W4 of the third semiconductor layer 122. In addition, the third electrode 121 may include a second open surface 121a extending from a side of the second light emitting device 120. The second open surface 121a may be electrically connected to at least one driving device 12 (e.g., driving device 12b). When the second open surface 121a and the at least one driving device 12 are connected to each other, they may be connected to each other through another medium. The second open surface 121a may be provided only on one side of the third electrode 121, and second open surfaces 121a and 121b may be provided on both sides of the third electrode 121 as shown in the device 100X in FIG. 3. The third semiconductor layer 122, the second active layer 123, the fourth semiconductor layer 124, and the fourth electrode 125 may have substantially the same widths. Also, the width W3 of the third electrode 121 may be the same as the width of the first bonding pillar AC1.

The second light emitting device 120 may have a structure in which a voltage is applied across the third electrode 121 and the fourth electrode 125 to activate the second active layer 123.

The second light emitting device 120 may be provided at a different height from the first light emitting device 110. Since the micro light emitting display device 100 emits color light corresponding to the first light emitting device 110 and the second light emitting device 120 having different heights, the micro light emitting area may be effectively secured.

In the micro light emitting display device 100 according to one or more embodiments, the first bonding pillar AC1 may be arranged between the backplane substrate 10 and the second light emitting device 120 so that the second light emitting device 120 is located at a different height from the first light emitting device 110. The first bonding pillar AC1 may be arranged between the bonding layer AL and the second light emitting device 120.

The first bonding pillar AC1 may be configured to be coupled to the second light emitting device 120 arranged thereon. The material of the first bonding pillar AC1 may include a polymer-based material. The material of the first bonding pillar AC1 may include at least one of epoxy, PI, and BCB. A material of the first bonding pillar AC1 may be the same as a material of the bonding layer AL. The material of the first bonding pillar AC1 may have higher etching selectivity than the materials of the first light emitting device 110 and the second light emitting device 120. For example, during the etching process for forming the first bonding pillar AC1, the first light emitting device 110 and the second light emitting device 120 may be hardly etched.

The first bonding pillar AC1 may have a pillar shape protruding upward. The first bonding pillar AC1 may have a shape protruding from the bonding layer AL toward the second light emitting device 120. A height of the first bonding pillar AC1 may be greater than a height of the first light emitting device 110. The height of the first bonding pillar AC1 may range from about 0.4 μm to about 10 μm.

The first bonding pillar AC1 may have a width greater than a width W4 of the second active layer 123 of the second light emitting device 120. The first bonding pillar AC1 may have a width equal to a width W3 of the third electrode 121. A planar shape of the first bonding pillar AC1 may be the same as a planar shape of the third electrode 121.

As described above, the micro light emitting display device 100 according to one or more embodiments has a structure in which the second light emitting device 120 is arranged above the first bonding pillar AC1, and there is no other material, such as a material layer corresponding to the first light emitting device 110 or the second light emitting device 120, below or in the middle of the first bonding pillar AC1. Accordingly, after the etching process for patterning the first and second light emitting devices 120, the etching process for patterning the first bonding pillar AC1 may be performed. If the etching process of the first and second light emitting devices 110 and 120 is performed after the etching process for forming the first bonding pillar AC1 has been performed, the side surface of the first bonding pillar AC1 may be damaged. However, in the micro light emitting display device 100 according to one or more embodiments, since the etching process of the first bonding pillar AC1 may be performed after the etching process of the first and second light emitting devices 110 and 120, damage to the side surface of the first bonding pillar AC1 may be prevented. This will be described in detail in the description of the method of manufacturing the micro light emitting display device 100.

The first light emitting device 110 and the second light emitting device 120 may have widths in micrometer size. Here, the widths may indicate the widths of the first light emitting device 110 and the second light emitting device 120. For example, the second width W2 of the first light emitting device 110 and the fourth width W4 of the second light emitting device 120 may range from about 0.1 μm to about 100 μm. Alternatively, the second width W2 of the first light emitting device 110 and the fourth width W4 of the second light emitting device 120 may range from about 0.1 μm to about 50 μm.

The micro light emitting display device 100 may be applied to, for example, a pentile pixel structure. The pentile pixel structure may share sub-pixels with other neighboring pixels. The pentile pixel structure may include, for example, a pixel including a red sub-pixel R and a green sub-pixel G, or a blue sub-pixel B and a green sub-pixel G. However, this is only an example, and various pixel structures are possible.

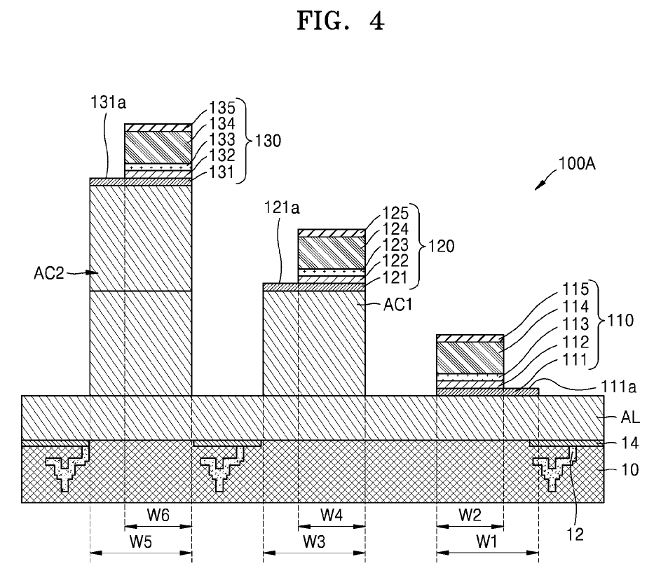

FIG. 4 is a diagram illustrating an example of a micro light emitting display device 100A in which a third light emitting device 130 is further provided in the micro light emitting display device 100 shown in FIG. 1, according to one or more embodiment. Description of aspects that are the same as or similar to those described above may be omitted.

Referring to FIG. 4, the micro light emitting display device 100A may include a first light emitting device 110, a second light emitting device 120, and a third light emitting device 130 to be spaced apart from each other on the backplane substrate 10 in the horizontal direction.

The third light emitting device 130 may be located at a different height from the first light emitting device 110 and the second light emitting device 120. For example, a second bonding pillar AC2 may be arranged between the backplane substrate 10 and the third light emitting device 130. The second bonding pillar AC2 may be arranged between the bonding layer AL and the third light emitting device 130.

The second bonding pillar AC2 may have a pillar shape protruding upward. The second bonding pillar AC2 may have a shape protruding from the bonding layer AL toward the third light emitting device 130. A height of the second bonding pillar AC2 may be greater than a height of the first bonding pillar AC1. A height of the second bonding pillar AC2 may be greater than a height of the second light emitting device 120. The height of the second bonding pillar AC2 may range from about 0.4 μm to about 10 μm.

The second bonding pillar AC2 may have a width greater than a width W6 of the third active layer of the third light emitting device 130. The second bonding pillar AC2 may have a width equal to a width W5 of a fifth electrode 131. A planar shape of the second bonding pillar AC2 may be the same as a planar shape of the fifth electrode 131.

The second bonding pillar AC2 may be configured to be coupled to the third light emitting device 130 arranged thereon. The material of the second bonding pillar AC2 may include a polymer-based material. The material of the second bonding pillar AC2 may include at least one of epoxy, PI, and BCB. The second bonding pillar AC2 may include the same material as the bonding layer AL and the first bonding pillar AC1.

The third light emitting device 130 may include a fifth electrode 131, a fifth semiconductor layer 132, a third active layer 133 that emits light of a third wavelength, a sixth semiconductor layer 134, and a sixth electrode 135, which are stacked in order in a direction perpendicular to the upper surface of the backplane substrate 10 (e.g., the vertical direction).

The third light emitting device 130 may be provided at a different height from the first light emitting device 110, and may be provided at a different height from the second light emitting device 120. The third light emitting device 130 may be provided at a higher position than the first light emitting device 110 and the second light emitting device 120. That is, the first light emitting device 110 may have a top surface at a first height, the second light emitting device 120 may have a top surface at a second height greater than the first height, and the third light emitting device 130 may have a top surface at a third height that is greater than the second height and the first height.

The fifth semiconductor layer 132 may include a first type semiconductor. For example, the fifth semiconductor layer 132 may include a p-type semiconductor. Alternatively, the fifth semiconductor layer 132 may include an n-type semiconductor. The fifth semiconductor layer 132 may include a group III-V-based p-type semiconductor, for example, p-GaN, p-InGaN, p-AlInGaN, or p-AlGaInP. The fifth semiconductor layer 132 may have a single-layer structure or a multi-layer structure.

The third active layer 133 may be provided on a top surface of the fifth semiconductor layer 132. The third active layer 133 may generate light of a third wavelength, and the third wavelength may be different from the first wavelength and may be also different from the second wavelength. The third wavelength light may include, for example, a blue light wavelength. However, the third active layer 133 is not limited thereto.

The third active layer 133 may have a MQW structure or a SQW structure. The third active layer 133 may include a group III-V-based semiconductor, for example, GaN, InGaN, AlInGaN, or AlGaInP. The third active layer 133 may include a material different from those of the first active layer 113 and the second active layer 123. Here, the different materials may include not only cases in which constituent elements are different, but also cases in which constituent elements are the same and composition ratios are different.

The sixth semiconductor layer 134 may be provided on a top surface of the third active layer 133. The sixth semiconductor layer 134 may include, for example, an n-type semiconductor. Alternatively, the sixth semiconductor layer 134 may include a p-type semiconductor. The sixth semiconductor layer 134 may include a group III-V-based n-type semiconductor, for example, n-GaN, n-InGaN, n-AlInGaN, or n-AlGaInP. The sixth semiconductor layer 134 may have a single-layer structure or a multi-layer structure.

A width W5 of the fifth electrode 131 may be greater than a width W6 of the fifth semiconductor layer 132. In addition, the fifth electrode 131 may include a third open surface 131a extending from a side of the third light emitting device 130. The fifth electrode 131 may have multiple open surfaces extending from both sides of the third light emitting device 130 similar to the structure of the first electrode 111 and the second electrode 115 shown in the device 100X of FIG. 3. The third open surface 131a may be electrically connected to at least one corresponding driving device 12. When the third open surface 131a and the at least one driving device 12 are connected to each other, they may be connected to each other through another component. The third open surface 131a may be provided on either side of the fifth electrode 131, as well as on only one side of the fifth electrode 131. The widths of the fifth semiconductor layer 132, the third active layer 133, the sixth semiconductor layer 134, and the sixth electrode 135 may be the same.

The third light emitting device 130 may have a structure in which a voltage is applied across the fifth electrode 131 and the sixth electrode 135 to activate the third active layer 133. That is, when a voltage is applied across the fifth electrode 131 and the sixth electrode 135, electrons and holes may be combined in the third active layer 133 to emit light having a third wavelength.

As described above, the micro light emitting display device 100 according to one or more embodiments has a structure in which the third light emitting device 130 is arranged above the second bonding pillar AC2, and there is no other material, for example, a material layer corresponding to the first and second light emitting devices 110 and 120, below or in the middle of the second bonding pillar AC2. Accordingly, after the etching process for patterning the first, second, and third light emitting devices 110, 120, and 130, the etching process for patterning the first and second bonding pillars AC1 and AC2 may be performed. If at least one of the first, second, and third light emitting devices 110, 120, and 130 is etched after the etching process for forming the first bonding pillar AC1 or the second bonding pillar AC2 has been performed, the side surface of the first bonding pillar AC1 or the second bonding pillar AC2 may be damaged. However, in the micro light emitting display device 100 according to one or more embodiments, since the etching process for the first bonding pillar AC1 and the second bonding pillar AC2 may be performed after the etching process for the first, second, and third light emitting devices 110, 120, and 130, side damage to the first bonding pillar AC1 and the second bonding pillar AC2 may be prevented. This will be described in detail in the description of the method of manufacturing the micro light emitting display device 100A.

As described above, in the micro light emitting display device 100A, the first light emitting device 110, the second light emitting device 120, and the third light emitting device 130 that emit light of different wavelengths may be provided at different heights with respect to the backplane substrate 10. Since the micro light emitting display device 100A emits light from the first light emitting device 110, the second light emitting device 120, and the third light emitting device 130 having different heights, a light emitting area may be effectively secured.

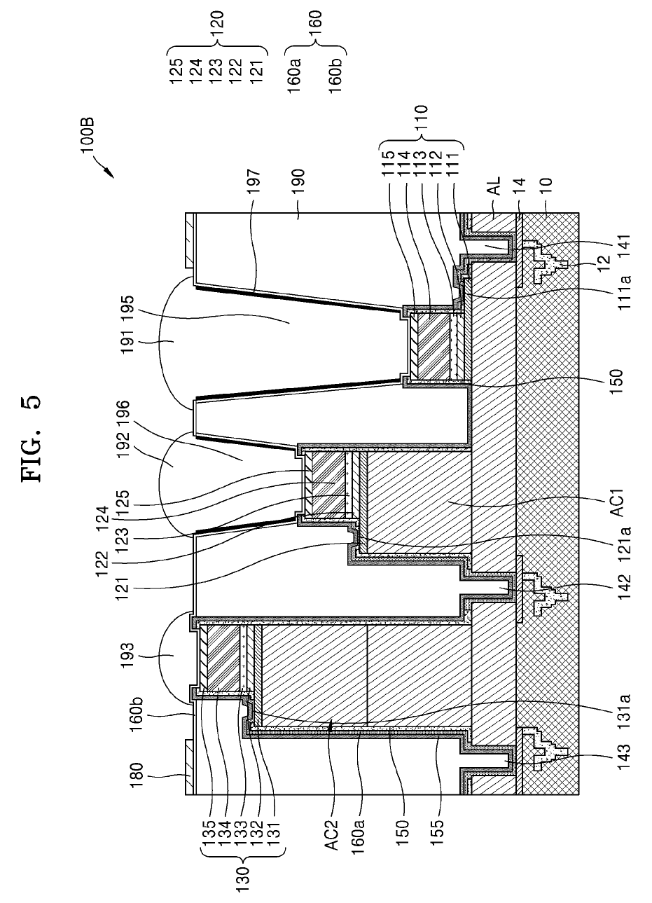

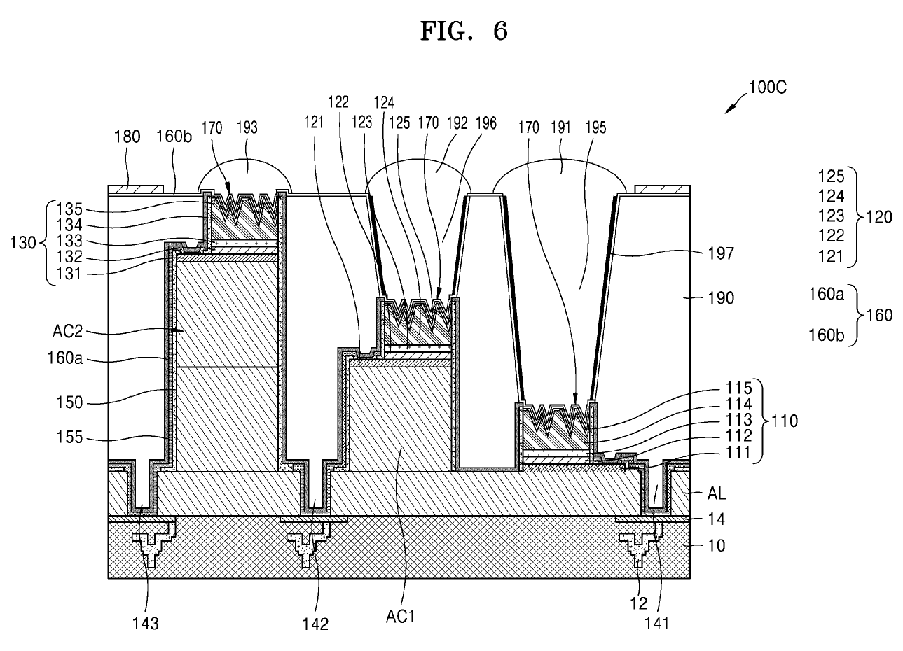

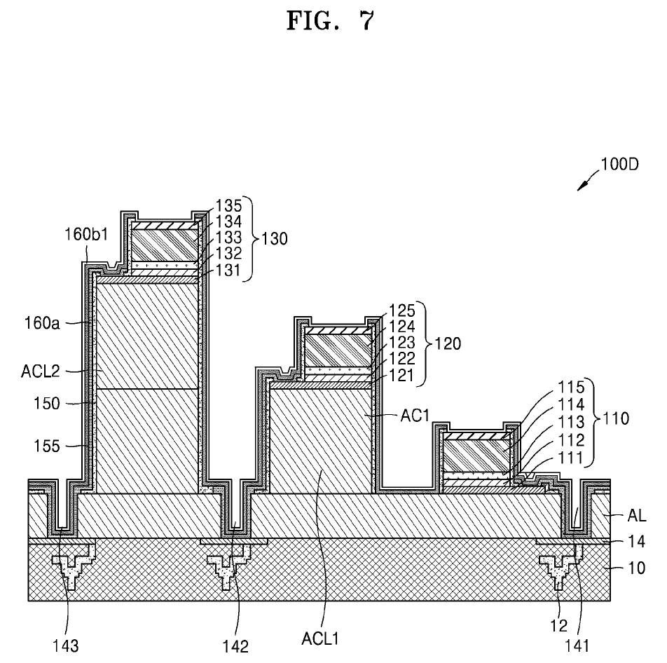

FIG. 5 is a diagram illustrating an electrode connection structure of the micro light emitting display device 100A of FIG. 4 according to one or more embodiments. FIG. 6 is a diagram illustrating another example of a micro light emitting display device 100C according to one or more embodiments. FIG. 7 is a diagram illustrating another example of a micro light emitting display device 100D according to one or more embodiments.

Referring to FIG. 5, a charge blocking layer 150 may be provided on a sidewall of the first light emitting device 110. The charge blocking layer 150 may expose the first open surface 111a of the first electrode 111 of the first light emitting device 110 and the top surface of the second electrode 115 thereof. A charge blocking layer 150 may be provided on a sidewall of the second light emitting device 120. The charge blocking layer 150 may expose the second open surface 121a of the third electrode 121 of the second light emitting device 120 and the top surface of the fourth electrode 125 thereof. A charge blocking layer 150 may be provided on a sidewall of the third light emitting device 130. The charge blocking layer 150 may expose the third open surface 131a of the fifth electrode 131 of the third light emitting device 130 and the top surface of the sixth electrode 135 thereof.

The charge blocking layer 150 may be provided in a region in which current supply is not required to block current supply. The charge blocking layer 150 may include at least one of, for example, Al₂O₃, HfO₂, AlN, and SiO₂. The charge blocking layer 150 arranged on the sidewall of the first light emitting device 110, the charge blocking layer 150 arranged on the sidewall of the second light emitting device 120, and the charge blocking layer 150 arranged on the sidewall of the third light emitting device 130 may include the same material, but are not limited thereto, and may include different materials in consideration of wavelengths of light emitted from the light emitting device.

The micro light emitting display device 100B may include a first groove 141, a second groove 142, and a third groove 143 spaced apart from each other and in the bonding layer AL. The first groove 141, the second groove 142, and the third groove 143 may be provided such that respective electrode pads 14 corresponding to the first groove 141, the second groove 142, and the third groove 143 are exposed.

A conductive layer 160 may be provided in each of the first light emitting device 110, the second light emitting device 120, and the third light emitting device 130. The conductive layer 160 may include a first conductive layer 160a for connecting each of the driving devices 12 with a p-type electrode of a light emitting device corresponding to each of the driving devices 12 and a second conductive layer 160b for connecting each of bus electrodes 180 with an n-type electrode of a light emitting device corresponding to each of bus electrodes 180.

The first conductive layer 160a may be provided in the first groove 141 to be connected to the electrode pad 14. In addition, the first conductive layer 160 a may be provided along the charge blocking layer 150 and may extend to the first open surface 111a of the first electrode 111 where the charge blocking layer 150 is not disposed. Accordingly, the first conductive layer 160a may connect the electrode pad 14 with the first electrode 111. Therefore, the first light emitting device 110 may be electrically connected to the driving device 12 through the first conductive layer 160a.

The first conductive layer 160a may be provided in the second groove 142 to be connected to the electrode pad 14. In addition, the first conductive layer 160a may be provided along the charge blocking layer 150 provided on a side surface of the first bonding pillar AC1, and may extend to the open surface 121a of the third electrode 121 of the second light emitting device 120 where the charge blocking layer 150 is not disposed. The first conductive layer 160a may connect the electrode pad 14 with the third electrode 121 of the second light emitting device 120. Therefore, the second light emitting device 120 may be electrically connected to the driving device 12 through the first conductive layer 160a.

The first conductive layer 160a may be provided in the third groove 143 to be connected to the electrode pad 14. In addition, the first conductive layer 160a may be provided along the charge blocking layer 150 provided on a side surface of the second bonding pillar AC2, and may extend to the open surface 131a of the fifth electrode 131 of the third light emitting device 130 where the charge blocking layer 150 is not disposed. The first conductive layer 160a may connect the electrode pad 14 with the fifth electrode 131 of the third light emitting device 130. Therefore, the third light emitting device 130 may be electrically connected to the driving device 12 through the first conductive layer 160a.

A second charge blocking layer 155 may be arranged on the first conductive layer 160a. The second charge blocking layer 155 may be arranged to cover the first conductive layer 160a and the charge blocking layer 150. The second charge blocking layer 155 may perform a function of separating the first conductive layer 160a from the second conductive layer 160b to be described later.

The second charge blocking layer 155 may be provided to expose top surfaces of the first light emitting device 110, the second light emitting device 120, and the third light emitting device 130. The second charge blocking layer 155 may be provided to expose the top surface of the second electrode 115 of the first light emitting device 110. The second charge blocking layer 155 may be provided to expose the top surface of the fourth electrode 125 of the second light emitting device 120. The second charge blocking layer 155 may be provided to expose the top surface of the sixth electrode 135 of the third light emitting device 130.

The second charge blocking layer 155 may be provided in a region in which current supply is not required to block current supply. The second charge blocking layer 155 may include at least one of, for example, Al₂O₃, HfO₂, AlN, and SiO₂. The second charge blocking layer 155 may include the same material as the charge blocking layer 150, but is not limited thereto and may include different materials.

The micro light emitting display devices 100B and 100C according to one or more embodiments may include a planarization layer 190 provided to cover portions the first light emitting device 110, the second light emitting device 120, and the third light emitting device 130. In one or more embodiments, the planarization layer 190 may expose top surfaces of the devices 110-130 as described below. The planarization layer 190 may flatten differences in heights of the first light emitting device 110, the second light emitting device 120, and the third light emitting device 130.

The planarization layer 190 may include, for example, an acrylic polymer. However, the planarization layer 190 is not limited thereto. The planarization layer 190 may include a transparent material, but is not necessarily limited thereto, and may include an opaque material.

The planarization layer 190 may be provided up to the height of the top surface of the third light emitting device 130. For example, the top surface of the planarization layer 190 and the top surface of the third light emitting device 130 may be at the same height. However, the height of the planarization layer 190 is not limited thereto.

The planarization layer 190 may be configured to expose a top surface of the first light emitting device 110, a top surface of the second light emitting device 120, and a top surface of the third light emitting device 130. A first hole 195 may be provided in the planarization layer 190 to expose the top surface of the first light emitting device 110, and a second hole 196 may be provided to expose the top surface of the second light emitting device 120. A separate hole may not be provided in the upper portion of the third light emitting device 130. However, a hole in the upper portion of the third light emitting device 130 may be provided.

The conductive layer 160 may further include a second conductive layer 160b for connecting a bus electrode 180 with an n-type electrode of a light emitting device corresponding to the bus electrode 180. The first conductive layer 160a and the second conductive layer 160b are separated from each other, and may serve as a wiring line.

The second conductive layer 160b may include a conductive material, and for example, the second conductive layer 160b may include a transparent electrode material. The second conductive layer 160b may include a transparent electrode material and may be provided on each of the light emitting devices 110, 120, and 130 to transmit light emitted from each of the light emitting devices 110, 120, and 130.

The second conductive layer 160b may be provided on a top surface of the second electrode 115 and may extend along the planarization layer 190. The second conductive layer 160b may be provided on a top surface of the fourth electrode 125 and may extend along the planarization layer 190. The second conductive layer 160b may be provided on a top surface of the sixth electrode 135 and may extend along the planarization layer 190.

The second conductive layer 160b may be connected to the bus electrode 180. For example, the bus electrode 180 may be arranged on the second conductive layer 160b. The bus electrode 180 may include a material having a higher conductivity than a material of the second conductive layer 160b. For example, when the material of the second conductive layer 160b is ITO, the bus electrode 180 may include at least one of aluminum, chromium, and copper. The bus electrode 180 may be arranged in a lattice shape. The bus electrode 180 may be a common electrode.

A corresponding lens may be arranged on each of the first light emitting device 110, the second light emitting device 120, and the third light emitting device 130. A first lens 191 may be arranged on the first light emitting device 110, a second lens 192 may be arranged on the second light emitting device 120, and a third lens 193 may be arranged on the third light emitting device 130. The first lens 191 may be provided in the first hole 195, and the second lens 192 may be provided in the second hole 196.

The first lens 191 may fill the first hole 195, and a top surface thereof may have a convex shape. That is, the first lens 191 may be formed as a single body from the upper portion of the first light emitting device 110 to the convex portion. Here, the first lens 191 is provided to fill the first hole 195, but it is also possible to fill the first hole 194 with another layer and have the first lens on top of the first hole 195. That is, the first lens 191 may include a portion of filling the first hole 195 and a convex portion, which are formed as separate bodies. The first lens 191 may be arranged to have the same central axis as the central axis of the first active layer 113.

The second lens 192 may fill the second hole 196, and an upper surface thereof may have a convex shape. The third lens 193 may be provided above the third light emitting device 130 (or may fill a third hole in embodiments where a third hole is provided over the third light emitting device 130). That is, the second lens 192 may be formed as a single body from the upper portion of the second light emitting device 120 to the convex portion. Alternatively, as described with respect to the first lens 191, the second lens 192 may have a portion for filling the second hole 196 and the convex portion as separate bodies. The second lens 192 may be arranged to have the same central axis as the central axis of the second active layer 123.

The third lens 193 may be provided above the third light emitting device 130 and may have a convex shape. The third lens 193 may be provided directly above the third light emitting device 130 without a separate hole portion. However, it is also possible to have a structure in which the third lens 193 is provided in the hole portion.

A reflective layer 197 for reflecting light may be provided on sidewalls of the first and second holes 195 and 196. The light emitted from the corresponding light emitting device may be reflected by the reflective layer 197 to emit the light upward with high efficiency. The reflective layer 197 may include, for example, Al or Ag.

In the micro light emitting display device 100B, convex portions of the first lens 191, the second lens 192, and the third lens 193 may be arranged at the same height. Thus, the light emitted from the first light emitting device 110, the second light emitting device 120, and the third light emitting device 130 which are located at different heights may be effectively condensed.

Referring to FIG. 6, a micro light emitting display device 100C according to one or more embodiments may include an uneven structure 170 on a top surface of the first light emitting device 110, a top surface of the second light emitting device 120, and a top surface of the third light emitting device 130. The uneven structure 170 may be provided on the second semiconductor layer 114 and the second electrode 115 of the first light emitting device 110, and the second conductive layer 160b may be arranged above the first light emitting device 110. The uneven structure 170 may be provided on the fourth semiconductor layer 124 and the fourth electrode 125 of the second light emitting device 120, and the second conductive layer 160b may be arranged above the second light emitting device 120. The uneven structure 170 may be provided on the sixth semiconductor layer 134 and the sixth electrode 135 of the third light emitting device 130, and the second conductive layer 160b may be arranged above the third light emitting device 130. The uneven structure 170 may increase external quantum efficiency of light emitted from the first light emitting device 110.

In the micro light emitting display devices 100, 100X, 100A, 100B, and 100C according to one or more embodiments described above, an example in which the second conductive layer 160b is arranged on the planarization layer 190 has been described. However, the arrangement of the second conductive layer 160b in the micro light emitting display devices 100, 100A, 100B, and 100C according to one or more embodiments is not necessarily limited thereto, and may vary. For example, as shown in FIG. 7, in the micro light emitting display device 100D according to one or more embodiments, a second conductive layer 160b1 may be arranged on the second charge blocking layer 155 without the planarization layer 190.

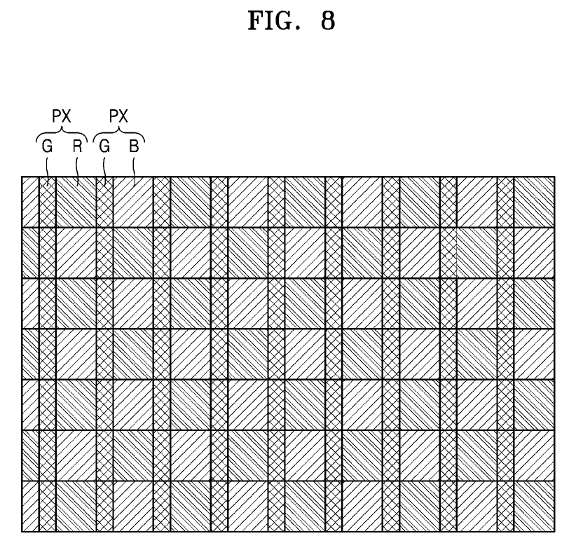

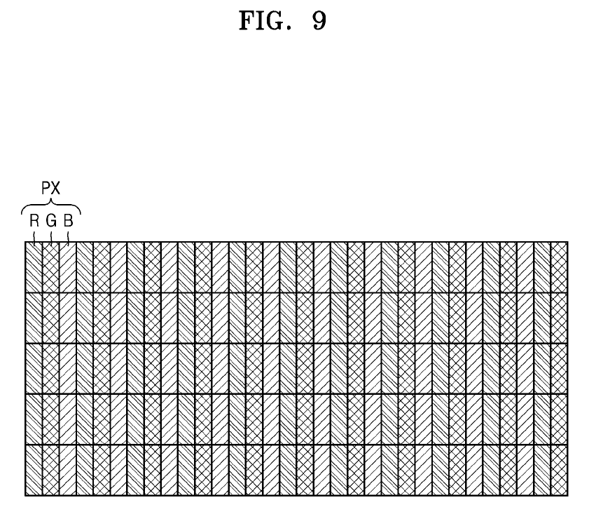

FIG. 8 is a diagram illustrating an example of a pixel structure of a micro light emitting display device according to one or more embodiments. FIG. 9 is a diagram illustrating another example of a pixel structure of a micro light emitting display device according to one or more embodiments.

Referring to FIG. 8, the micro light emitting display device includes a plurality of pixels PX, and each pixel PX may be one unit for displaying an image. Each of the pixels PX may include sub-pixels emitting different colors. An image may be displayed by controlling the color and light intensity from each sub-pixel.

The pixel structure shown in FIG. 8 may represent a so-called pentile structure. The pixel PX may include a first sub-pixel G that emits green light and a second sub-pixel R that emits red light. Alternatively, the pixel PX may include a first sub-pixel G that emits green light and a second sub-pixel B that emits blue light. A sub-pixel emitting red light and a sub-pixel emitting blue light may be shared with neighboring pixels to form a color. The pixel structure may be applied to, for example, the micro light emitting display device 100 illustrated in FIG. 1 as well as other micro light emitting display devices, such as devices 100X, 100A, 100B, 100C, and 100D, as described herein.

Referring to FIG. 9, the pixel PX may include a first sub-pixel R that emits red light, a second sub-pixel G that emits green light, and a third sub-pixel B that emits blue light. The pixel structure may be applied to, for example, the micro light emitting display device 100A illustrated in FIG. 4.

The micro light emitting display devices 100, 100X, 100A, 100B, 100C, and 100D according to one or more embodiments described above may emit light from a plurality of light emitting devices arranged at different heights. The plurality of light emitting devices may emit light having different wavelengths to form a color image. The micro light emitting display devices 100, 100X, 100A, 100B, 100C, and 100D may form a color image without a color conversion member or a color filter that converts blue light into light of another wavelength.

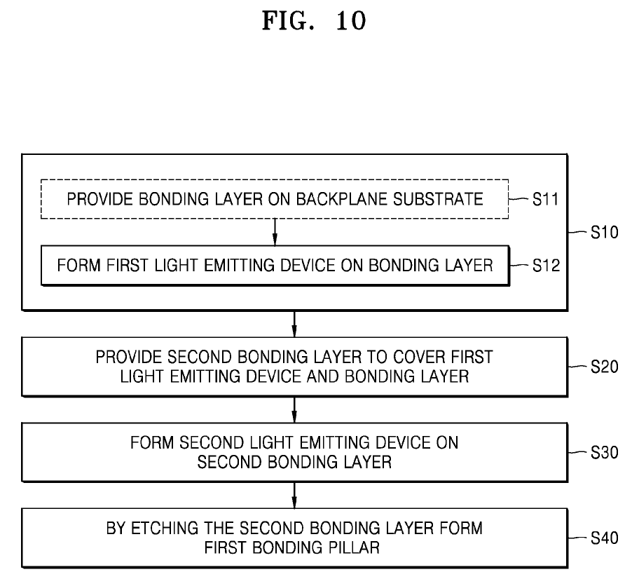

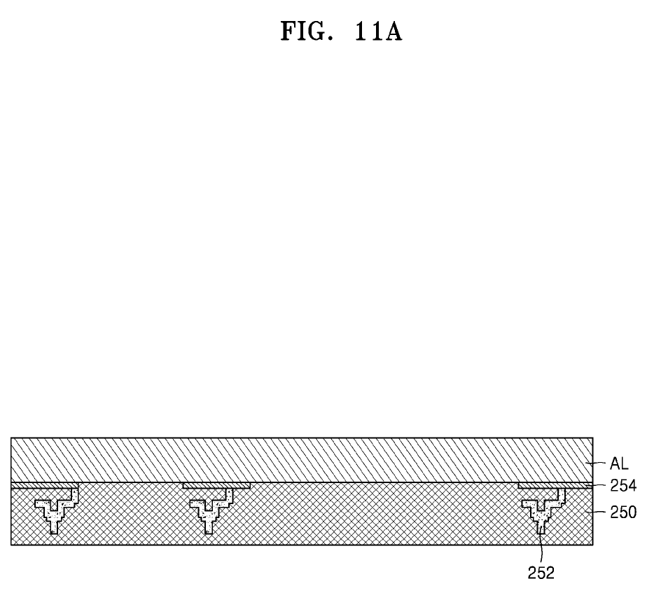

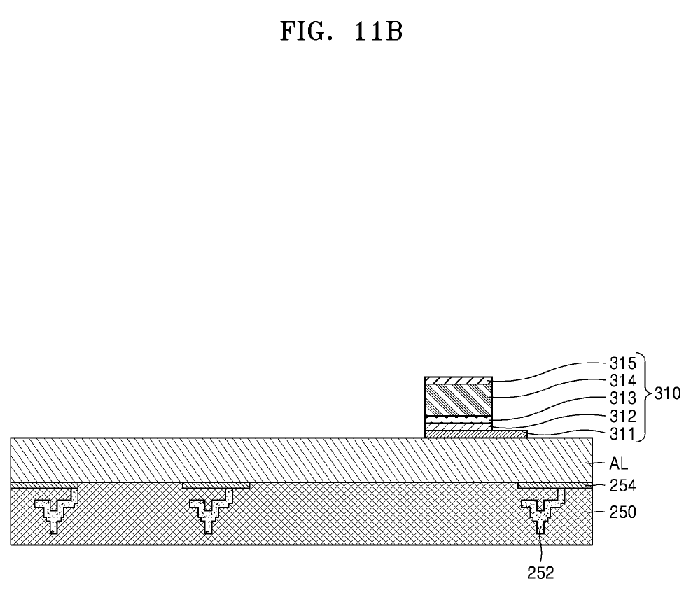

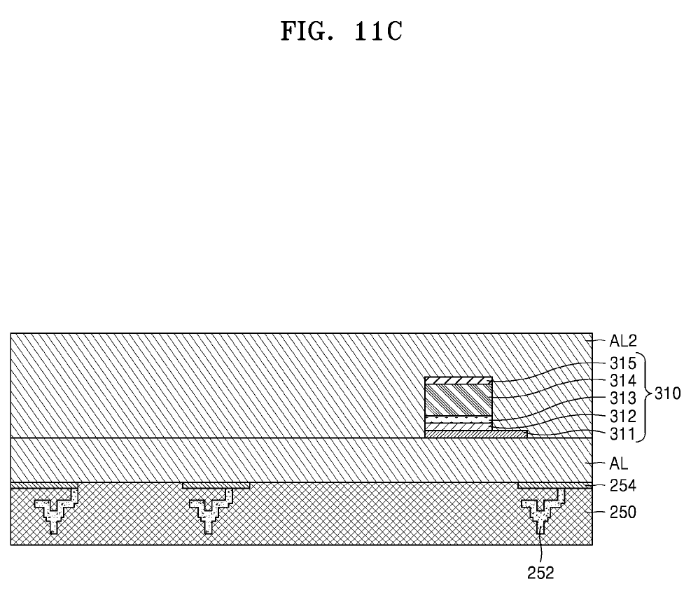

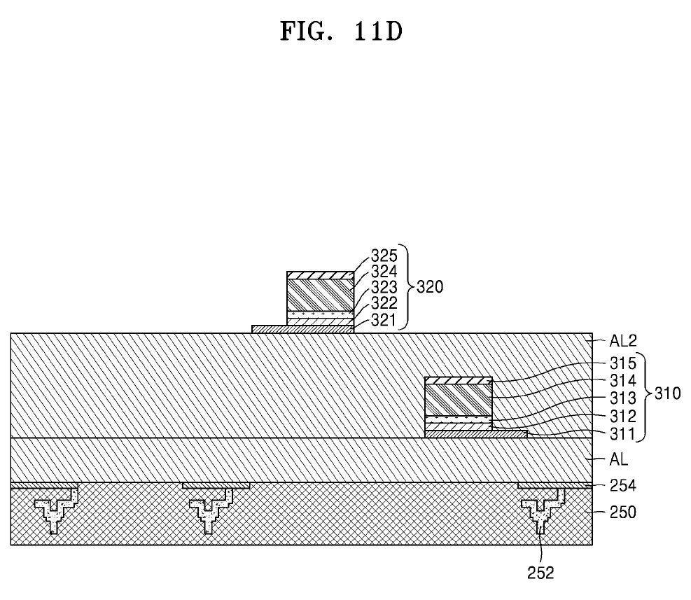

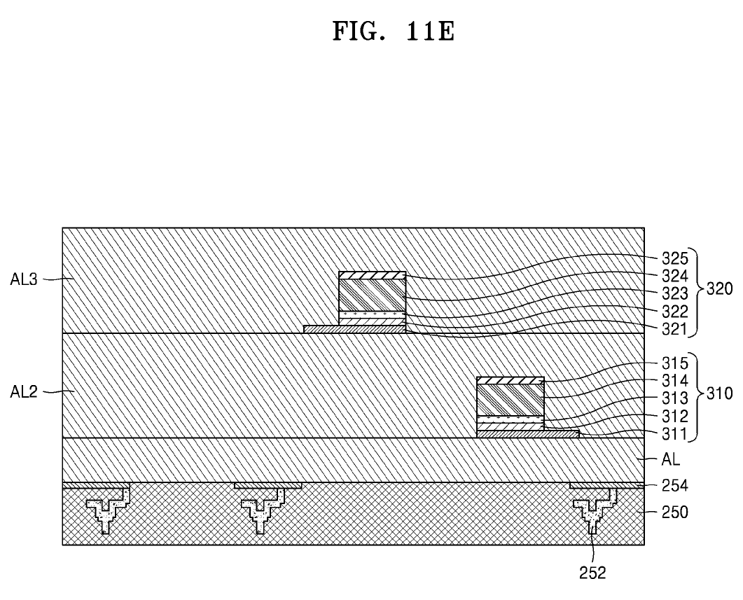

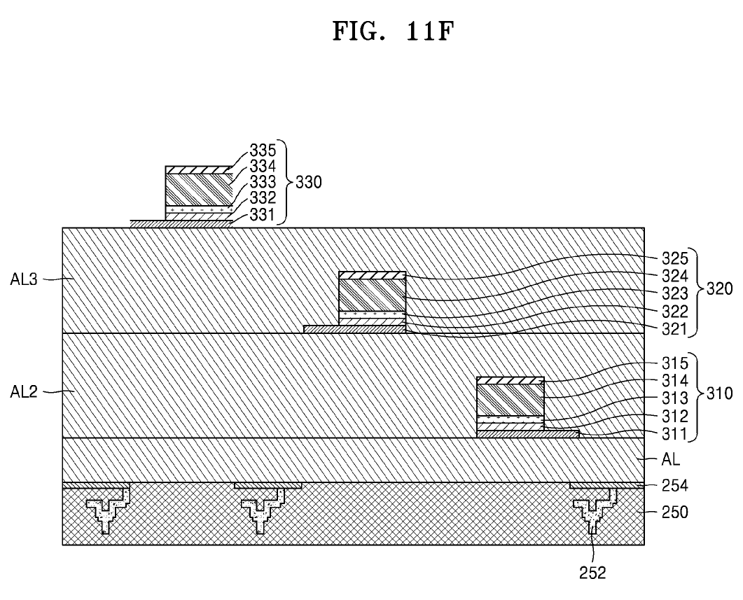

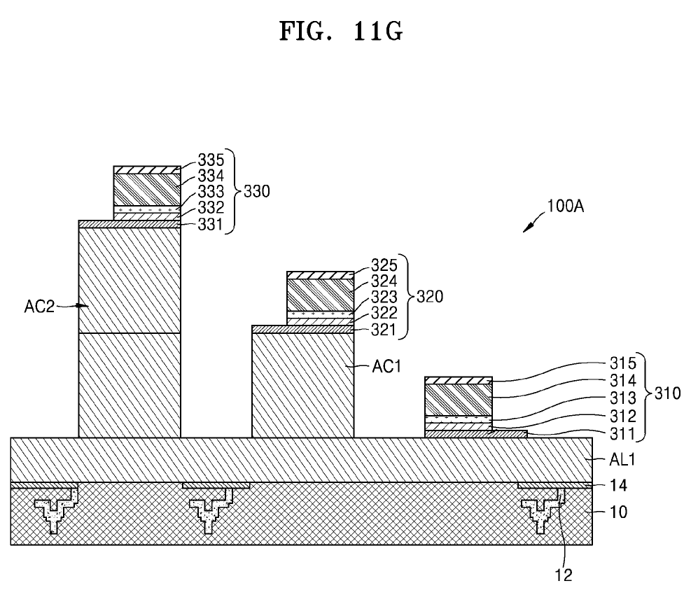

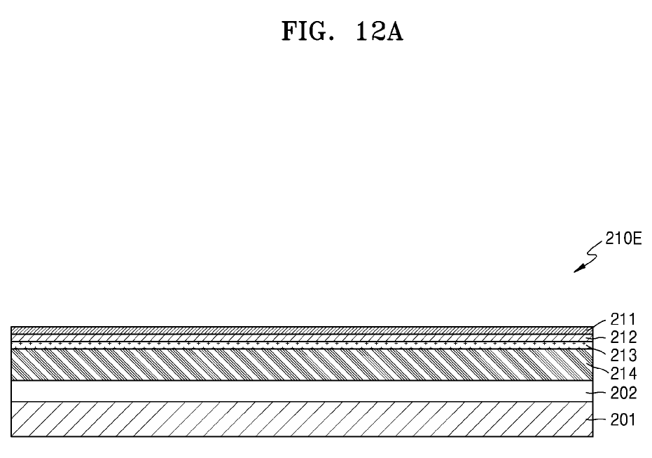

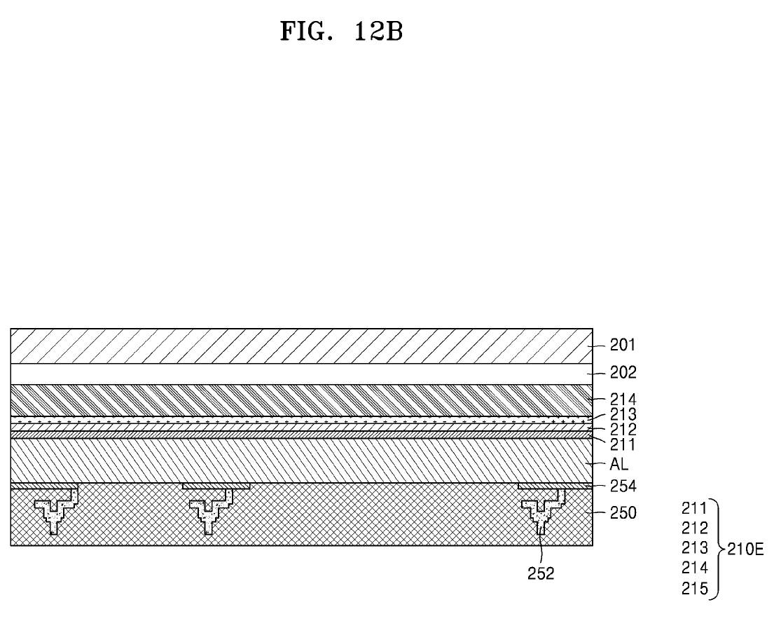

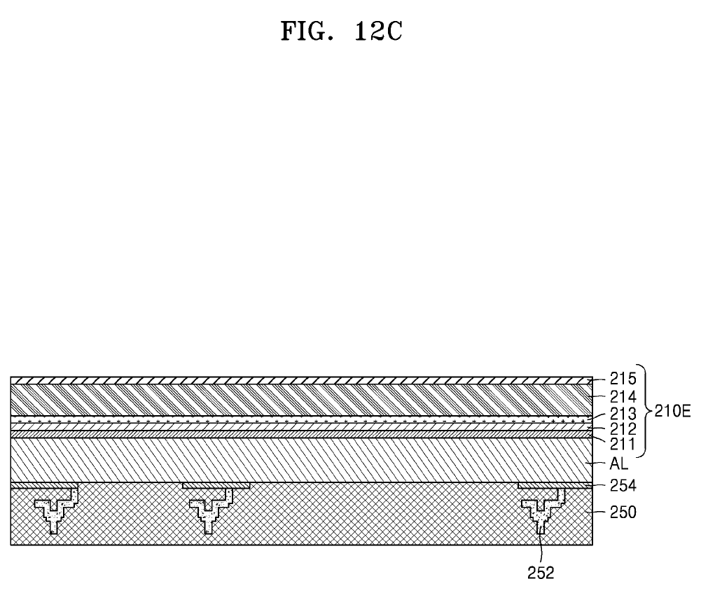

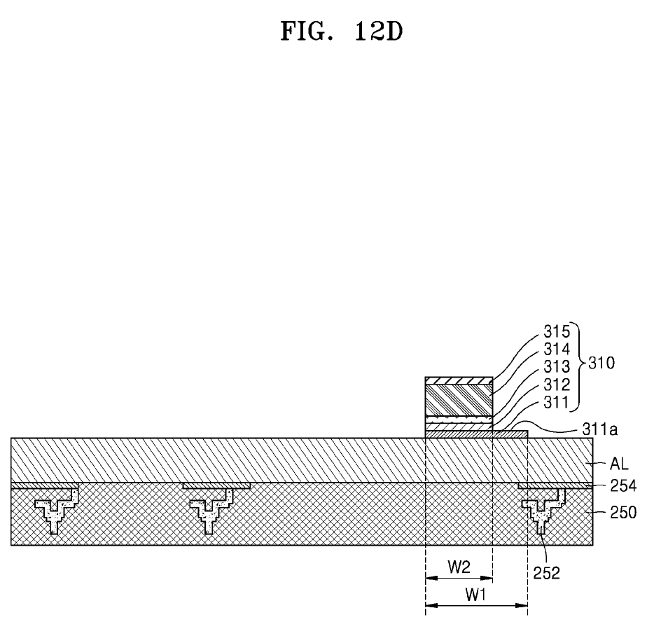

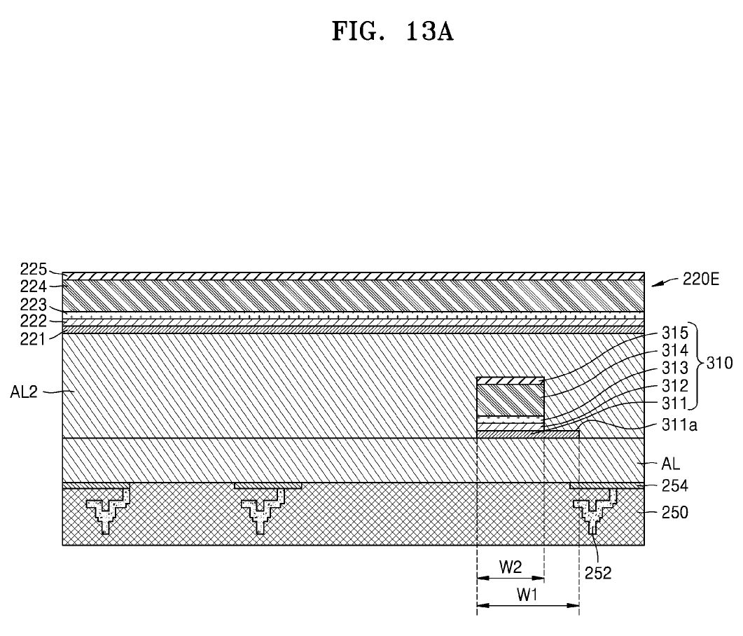

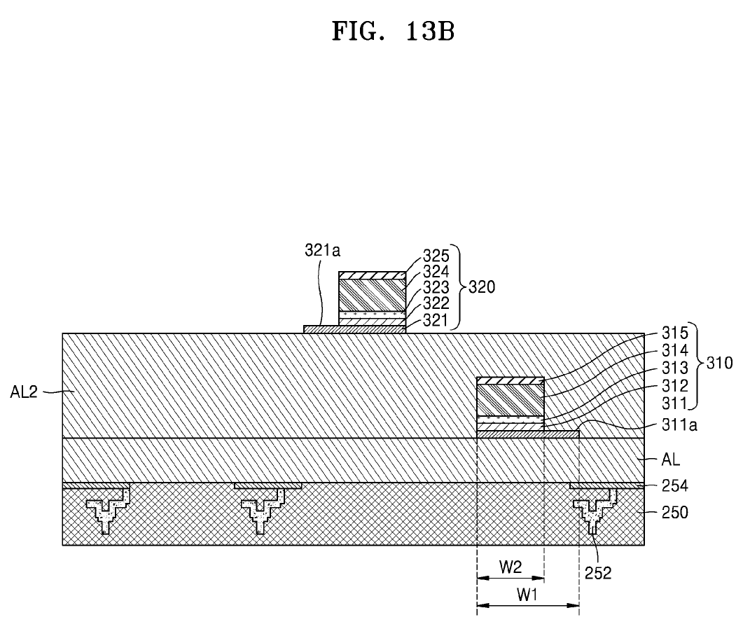

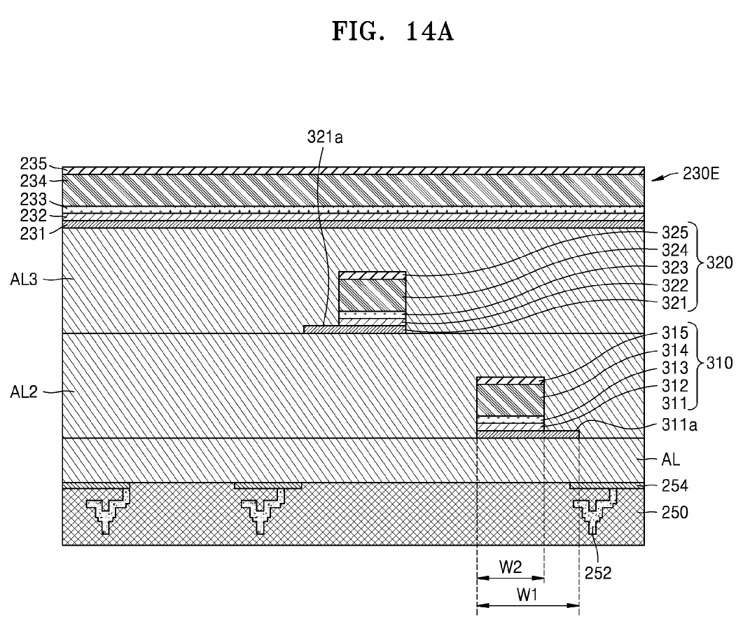

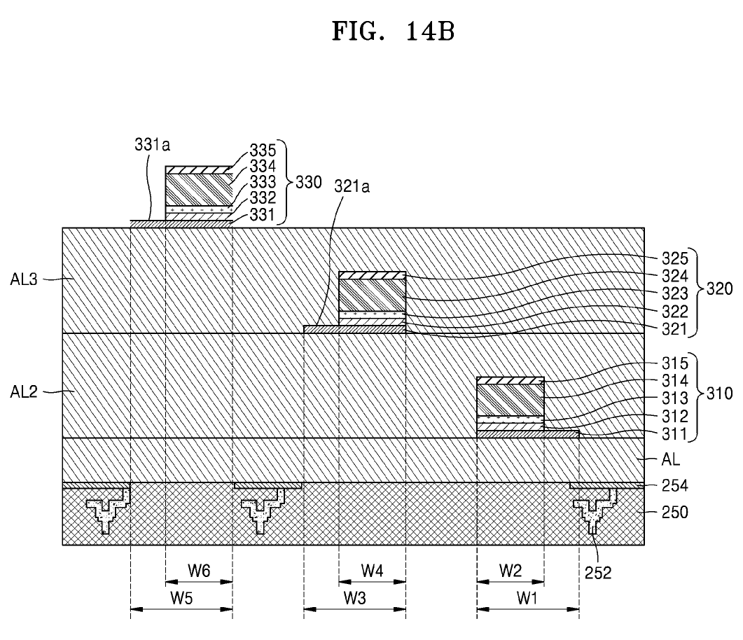

FIG. 10 is a flowchart illustrating a method of manufacturing a micro light emitting display device according to one or more embodiments. FIGS. 11A to 11G are diagrams illustrating a method of manufacturing a micro light emitting display device according to one or more embodiments; FIGS. 12A to 12D are diagrams illustrating an operation of arranging a first light emitting device on a bonding layer. FIGS. 13A and 13B are diagrams illustrating an operation of arranging a second light emitting device on a first bonding layer. FIGS. 14A and 14B are diagrams schematically illustrating an operation of arranging a third light emitting device on a second bonding layer;

Referring to FIGS. 10, 11A, and 11B, in a method of manufacturing a micro light emitting display device according to one or more embodiments, a first light emitting device 310 may be formed on the backplane substrate 250 with a bonding layer AL therebetween in operation S10.

As an example for forming the first light emitting device 310 on the backplane substrate 250, the bonding layer AL may be provided on the backplane substrate 250 in operation S11, and the first light emitting device 310 may be formed on a portion of a top surface of the bonding layer AL in operation S12.

The backplane substrate 250 may include a driving device 252. The backplane substrate 250 may include an electrode pad 254 connected to the driving device 252. The driving device 252 may include at least one transistor and at least one capacitor.

The bonding layer AL may include epoxy, PI, BCB, etc. In FIGS. 10 and 11A, the bonding layer AL is formed on the backplane substrate 250, but the formation of the bonding layer AL is not necessarily limited thereto. For example, the bonding layer AL may be formed on the first epitaxial electrode 211 to be described later, or the bonding layer AL may be formed on both the backplane substrate 250 and the first epitaxial electrode 211.

The arranging of the first light emitting device 310 may include transferring a first epitaxial structure 210E to the bonding layer AL and then patterning the transferred first epitaxial structure 210E.

Referring to FIG. 12A, the arranging of the first light emitting device 310 may include forming the first epitaxial structure 210E. To form the first epitaxial structure 210E, a second epitaxial semiconductor layer 214, a first epitaxial active layer 213, a first epitaxial semiconductor layer 212, and a first epitaxial electrode 211 may be sequentially deposited on an epitaxial substrate 201. In the specification, expressions such as “first”, “second”, etc. may be used to distinguish one component from another and are not limited to representing an order. In addition, “in order” and “sequentially” represent the order of layers, and do not exclude the intervention of other layers. The second epitaxial semiconductor layer 214, the first epitaxial active layer 213, the first epitaxial semiconductor layer 212, and the first epitaxial electrode 211 may be formed using, for example, a chemical vapor deposition (CVD) process, a physical vapor deposition (PVD) process, or an atomic layer deposition (ALD) process.

The epitaxial substrate 201 may include, for example, silicon, sapphire, GaAs or GaN. However, embodiments are not limited thereto, and various epitaxial substrates 201 may be used. The second epitaxial semiconductor layer 214 may include an n-type semiconductor layer. However, in some cases, the second epitaxial semiconductor layer 214 may include a p-type semiconductor layer. For example, the second epitaxial semiconductor layer 214 may include a group III-V compound semiconductor doped in an n-type. The first epitaxial active layer 213 may include a material that emits light of a first wavelength. For example, the first epitaxial active layer 213 may include a material that emits red light. However, embodiments are not limited thereto. The first epitaxial semiconductor layer 212 may include a p-type semiconductor layer. However, in some cases, the first epitaxial semiconductor layer 212 may include an n-type semiconductor layer. For example, the first epitaxial semiconductor layer 212 may include a group III-V compound semiconductor doped in a p-type.

A buffer layer 202 may be further formed between the epitaxial substrate 201 and the second epitaxial semiconductor layer 214. The buffer layer 202 may include a single-layer or multi-layer structure, and may assist the second epitaxial semiconductor layer 214 in growing. The buffer layer 202 may relieve stress due to a lattice constant difference between the epitaxial substrate 201 and the second epitaxial semiconductor layer 214. For example, the buffer layer 202 may be formed using a CVD process, a PVD process, or an ALD process. The lattice constant of the buffer layer 202 may have a value between the lattice constant of the epitaxial substrate 201 and the lattice constant of the second epitaxial semiconductor layer 214, or may have the same value as the lattice constant of the second epitaxial semiconductor layer 214. The buffer layer 202 may include, for example, a group III-V compound semiconductor such as GaN, GaP, GaAs, or the like. In addition, the buffer layer 202 may be doped in the same conductivity type as the second epitaxial semiconductor layer 214. For example, if the second epitaxial semiconductor layer 214 is doped in the n-type, the buffer layer 202 may include n-GaN, n-GaP, or n-GaAs, and if the second epitaxial semiconductor layer 214 is doped in the p-type, the buffer layer 202 may include p-GaN, p-GaP, or p-GaAs.

The first epitaxial electrode 211 may include, for example, Ag, Au, Al, Cr, or Ni, or an alloy thereof. However, the first epitaxial electrode 211 is not limited thereto. As described above, a first epitaxial structure 210E may be formed.

Referring to FIG. 12B, the first epitaxial structure 210E of FIG. 12A may be inverted and transferred to the backplane substrate 250 of FIG. 11A. The first epitaxial structure 210E may be inverted and placed on the bonding layer AL. The backplane substrate 250 and the first epitaxial structure 210E may be coupled to each other by the bonding layer AL. Alternatively, the first epitaxial electrode 211, the first epitaxial semiconductor layer 212, the first epitaxial active layer 213 and the second epitaxial semiconductor layer 214 may be sequentially deposited on the bonding layer AL instead of being constructed with an epitaxial substrate and buffer layer, and then being inverted onto the bonding layer AL as described above.

Referring to FIG. 12C, the epitaxial substrate 201 of the first epitaxial structure 210E may be removed. When the buffer layer 202 is arranged between the epitaxial substrate 201 and the second epitaxial semiconductor layer 214, the epitaxial substrate 201 and the buffer layer 202 of the first epitaxial structure 210E may be removed. The epitaxial substrate 201 and the buffer layer 202 may be removed by, for example, a laser lift off method, a polishing method, or the like. The polishing method may be used in conjunction with the dry etching method. For example, when the epitaxial substrate 201 is a sapphire substrate, the epitaxial substrate 201 may be removed by a laser lift off method, and when the epitaxial substrate 201 is a silicon substrate, the epitaxial substrate 201 may be removed by a polishing method. The buffer layer 202 may be selectively removed. In addition, a second epitaxial electrode 215 may be formed on the second epitaxial semiconductor layer 214. The second epitaxial electrode 215 may include a transparent electrode material. However, the formation order of the second epitaxial electrode 215 is not necessarily limited thereto, and the second epitaxial electrode 215 may be formed after other layers have been formed.

Referring to FIG. 12D, the first epitaxial structure 210E may be etched to form a first light emitting device 310. The first light emitting device 310 may be arranged on a portion of the top surface of the bonding layer AL.

The first epitaxial structure 210E may be primarily etched to the depth of the first epitaxial electrode 211 using a first mask, and may be secondarily etched to the depth of the first epitaxial semiconductor layer 212 using a second mask, to thereby form the first light emitting device 310 having a mesa structure. A stacked structure having a first width W1 may be formed in the primary etching, and a first light emitting device 310 including a first active layer 313 having a second width W2 may be formed in the secondary etching. The first width W1 may be greater than the second width W2. Therefore, an open surface 311a may be formed on the first electrode 311.

The mask may include, for example, a SiO₂ hard mask. Regions not covered with a mask may be etched to a predetermined depth through, for example, a dry etching process to form the first light emitting device 310. In this case, the structure formed by the dry etching process may have an inclined sidewall. In order to make the width of the first light emitting device 310 relatively constant, a wet etching process may be additionally performed. The dry etching process may use, for example, an inductively coupled plasma (ICP). The wet etching process may be performed using, for example, a potassium hydroxide (KOH) solution or a tetramethyl ammonium hydroxide (TMAH) solution as an etching solution.

The first light emitting device 310 may include a first electrode 311, a first semiconductor layer 312, a first active layer 313, a second semiconductor layer 314, and a second electrode 315, which are sequentially stacked on a portion of the top surface of the bonding layer AL.

Referring to FIGS. 10 and 11C, in the method of manufacturing a micro light emitting display device according to one or more embodiments, a second bonding layer AL2 may be provided in operation S20 to cover the first light emitting device 310 and the bonding layer AL.

The second bonding layer AL2 may be provided on the bonding layer AL and the first light emitting device 310 to cover the first light emitting device 310 and a portion of the bonding layer AL where is not covered by the first light emitting device 310.

The second bonding layer AL2 may include at least one of epoxy, PI, and BCB. A material of the second bonding layer AL2 may be the same as a material of the bonding layer AL.

Referring to FIGS. 10 and 11D, in the method of manufacturing a micro light emitting display device according to one or more embodiments, a second light emitting device 320 may be formed on a portion of a top surface of a second bonding layer AL2 in operation S30.

The forming of the second light emitting device 320 may include transferring the second epitaxial structure 220E onto the second bonding layer AL2, as shown in FIG. 13A.

The forming of the second light emitting device 320 may include forming a second epitaxial structure 220E. To form the second epitaxial structure 220E, a third epitaxial electrode 221, a third epitaxial semiconductor layer 222, a second epitaxial active layer 223, and a fourth epitaxial semiconductor layer 224 may be sequentially deposited on the second bonding layer AL2. The fourth epitaxial semiconductor layer 224, the second epitaxial active layer 223, the third epitaxial semiconductor layer 222, and the third epitaxial electrode 221 may be formed using, for example, a CVD process, a PVD process, or an ALD process. The second epitaxial active layer 223 of the second epitaxial structure 220E may include a material emitting light of a second wavelength. The second wavelength may be different from the first wavelength. The second wavelength may include, for example, a green wavelength. However, embodiments are not limited thereto.

Although FIG. 13A shows that the layers 221-224 are deposited on the second bonding layer AL2, the second epitaxial structure 220E may be formed by a process that is substantially similar to the process of forming the first epitaxial structure 210E as shown in FIGS. 12A and 12B. That is, the second epitaxial structure 220E may include an epitaxial substrate, the fourth epitaxial semiconductor layer 224, the second epitaxial active layer 223, the third epitaxial semiconductor layer 222, and the third epitaxial electrode 221, which are sequentially stacked in order. A buffer layer may be further formed between an epitaxial substrate and the fourth epitaxial semiconductor layer 224. The second epitaxial structure 220E may be inverted such that the third epitaxial electrode 221 faces the second bonding layer AL2 and thus the second epitaxial structure 220E may be coupled to the upper portion of the second bonding layer AL2. Thereafter, an epitaxial substrate and a buffer layer may be removed from the second epitaxial structure 220E, and then a fourth epitaxial electrode may be formed. That is, the structure and formation process shown in FIGS. 12A, 12B and 12C, may be equally applied to the formation of the second epitaxial structure 220E, where the second epitaxial structure 220E may be inverted and placed on the second bonding layer AL2 instead of the first bonding layer AL on which the first epitaxial structure 210E is inverted and placed.

Referring to FIG. 13B, the arranging of the second light emitting device 320 on the second bonding layer AL2 may include etching the second epitaxial structure 220E. The second epitaxial structure 220E may be etched to form a second light emitting device 320 on the second bonding layer AL2. The second light emitting device 320 may be arranged so as not to overlap the first light emitting device 310 in the vertical direction.

The second epitaxial structure 220E may be primarily etched to the depth of the third epitaxial electrode 221 using a first mask, and may be secondarily etched to the depth of the third epitaxial semiconductor layer 222 using a second mask, to thereby form the second light emitting device 320 having a mesa structure. A stacked structure having a third width W3 may be formed in the primary etching, and a second light emitting device 320 including the second active layer 323 having a fourth width W4 may be formed in the secondary etching. The third width W3 may be greater than the fourth width W4. Therefore, an open surface 321a may be formed on the third electrode 321.

The mask may include, for example, a SiO₂ hard mask. Regions not covered with a mask may be etched to a predetermined depth through, for example, a dry etching process to form the second light emitting device 320. In this case, the structure formed by the dry etching process may have an inclined sidewall. In order to make the width of the second light emitting device 320 relatively constant, a wet etching process may be additionally performed. The dry etching process may use, for example, an ICP. The wet etching process may be performed using, for example, a KOH solution or a TMAH solution as an etching solution.

The second light emitting device 320 may include the third electrode 321, a third semiconductor layer 322, the second active layer 323, a fourth semiconductor layer 324, and a fourth electrode 325, which are sequentially stacked on a portion of the top surface of the second bonding layer AL2.

Referring to FIG. 11E, a third bonding layer AL3 may be provided on the second bonding layer AL2 and the second light emitting device 320. The third bonding layer AL3 may be arranged to cover the second bonding layer AL2 and the second light emitting device 320.

The third bonding layer AL3 may be arranged on the second bonding layer AL2 and the second light emitting device 320 to cover the first second light emitting device 320 and a portion of the second bonding layer AL2 where is not covered by the second light emitting device 320.

The third bonding layer AL3 may include at least one of epoxy, PI, and BCB. A material of the third bonding layer AL3 may be the same as a material of the bonding layer AL. A material of the third bonding layer AL3 may be the same as a material of the second bonding layer AL2.

Referring to FIG. 11F, in the method of manufacturing a micro light emitting display device according to one or more embodiments, the method may further include forming the third light emitting device 330 on a portion of the top surface of the third bonding layer AL3.

The arranging of the third light emitting device 330 on the third bonding layer AL3 may include transferring a third epitaxial structure 230E on the third bonding layer AL3, as shown in FIG. 14A.

The third epitaxial structure 230E may include an epitaxial substrate, a sixth epitaxial semiconductor layer 234, a third epitaxial active layer 233, a fifth epitaxial semiconductor layer 232, and a fifth epitaxial electrode 231, which are sequentially stacked in order. A buffer layer may be further formed between the epitaxial substrate and the sixth epitaxial semiconductor layer 234.

The third epitaxial active layer 233 of the third epitaxial structure 230E may include a material emitting light of a third wavelength. The third wavelength may be different from the first wavelength and the second wavelength. The third wavelength may include, for example, a blue wavelength. However, embodiments are not limited thereto.

The third epitaxial structure 230E may be turned upside down such that the fifth epitaxial electrode 231 faces the third bonding layer AL3 and thus the third epitaxial structure 230E may be coupled to the upper portion of the third bonding layer AL3. Thereafter, an epitaxial substrate and a buffer layer may be removed from the third epitaxial structure 230E, and then a sixth epitaxial electrode may be formed.

The process of transferring the third epitaxial structure 230E may be performed in the same manner as the method of transferring the first epitaxial structure 210E described above, and thus a detailed description thereof will be omitted. Furthermore, the third epitaxial structure 230E may be formed by sequentially depositing the fifth epitaxial electrode 231, the fifth epitaxial semiconductor layer 232, the third epitaxial active layer 233 and the sixth epitaxial semiconductor layer 234 on the third bonding layer AL3 instead of using an epitaxial substrate and inversion process as described above.

Referring to FIG. 14B, the forming of the third light emitting device 330 on the third bonding layer AL3 may include etching the third epitaxial structure 230E. The third epitaxial structure 230E may be etched to form a third light emitting device 330 on the third bonding layer AL3. The third light emitting device 330 may be arranged so as not to overlap the first light emitting device 310 and the second light emitting device 320 in the vertical direction.

The third epitaxial structure 230E may be primarily etched to the depth of the fifth epitaxial electrode 231 using a first mask, and may be secondarily etched to the depth of the fifth epitaxial semiconductor layer 232 using a second mask, to thereby form the third light emitting device 330 having a mesa structure. A stacked structure having a fifth width W5 may be formed in the primary etching, and a third light emitting device 330 including the third active layer 333 having a sixth width W6 may be formed in the secondary etching. The fifth width W5 may be greater than the sixth width W6. Therefore, an open surface 331a may be formed in the fifth electrode 331.

The mask may include, for example, a SiO₂ hard mask. Regions not covered with a mask may be etched to a predetermined depth through, for example, a dry etching process to form the third light emitting device 330. In this case, the structure formed by the dry etching process may have an inclined sidewall. In order to make the width of the third light emitting device 330 relatively constant, a wet etching process may be additionally performed. The dry etching process may use, for example, an ICP. The wet etching process may be performed using, for example, a KOH solution or a TMAH solution as an etching solution.

The third light emitting device 330 may include the fifth electrode 331, a fifth semiconductor layer 332, the third active layer 333, a sixth semiconductor layer 334, and a sixth electrode 335, which are sequentially stacked on a portion of the top surface of the second bonding layer AL2.

Referring to FIGS. 10 and 11G, a method of manufacturing a micro light emitting display device according to one or more embodiments may include forming the first bonding pillar AC1 by etching the second bonding layer AL2 in operation S40. For example, the second bonding layer AL2 and the third bonding layer AL3 may be etched so that the first bonding pillar AC1 is formed under the second light emitting device 320 and the second bonding pillar AC2 is formed under the third light emitting device 330.

The height of the first bonding pillar AC1 may be the same as the height of the second bonding layer AL2. The height of the first bonding pillar AC1 may be greater than the height of the first light emitting device 310. The height of the first bonding pillar AC1 may range from about 0.4 μm to about 10 μm.

The height of the second bonding pillar AC2 may be equal to the sum of the height of the second bonding layer AL2 and the height of the third bonding layer AL3. The height of the second bonding pillar AC2 may be greater than the height of the first bonding pillar AC1. The height of the second bonding pillar AC2 may be greater than the height of the second light emitting device 320. The height of the second bonding pillar AC2 may range from about 0.4 μm to about 10 μm.

The etching of the second bonding layer AL2 and the third bonding layer AL3 may be performed by a material having high etching selectivity with respect to the second bonding layer AL2 and the third bonding layer AL3. As an example of the etching material of the second bonding layer AL2 and the third bonding layer AL3, at least one of C₄F₈, CHF₃, and O₂ may be used.

As described above, since the patterning of the first and second bonding pillars AC1 and AC2 proceeds after the first, second and third light emitting devices 310, 320, and 330 are arranged or formed, the first bonding pillar AC1 and the second bonding pillar AC2 may be prevented from being damaged by etching to form the first, second and third light emitting devices 310, 320, and 330.

The first light emitting device 310 is arranged on the bonding layer AL, the second light emitting device 320 is arranged on the first bonding pillar AC1 higher than the bonding layer AL, and the third light emitting device 330 is arranged on the second bonding pillar AC2 higher than the first bonding pillar AC1, so that the first light emitting device 310, the second light emitting device 320, and the third light emitting device 330 may be arranged at different heights on the backplane substrate 250.

As described above, in the method of manufacturing a micro light emitting display device according to one or more embodiments, side damage to the first bonding pillar AC1 and the second bonding pillar AC2 may be prevented by sequentially forming the bonding layer AL, the first light emitting device 310, the second bonding layer AL2, the second light emitting device 320, the third bonding layer AL3, and the third light emitting device 330, on the backplane substrate 250, and processing the second bonding layer AL2 and the third bonding layer AL3 in a one-time etching process in order to form the first bonding pillar AC1 and the second bonding pillar AC2. Although the sequential formation of the bonding layer AL, the first light emitting device 310, the second bonding layer AL2, the second light emitting device 320, the third bonding layer AL3, and the third light emitting device 330 has been described with reference to FIG. 11F, only the formation of the second bonding layer AL2 and the second light emitting device 320 may be performed to manufacture the micro light emitting display device of FIG. 1.

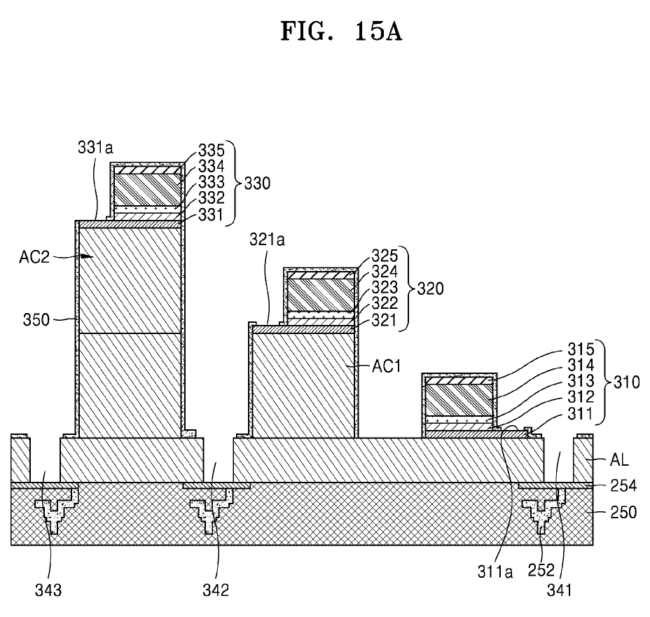

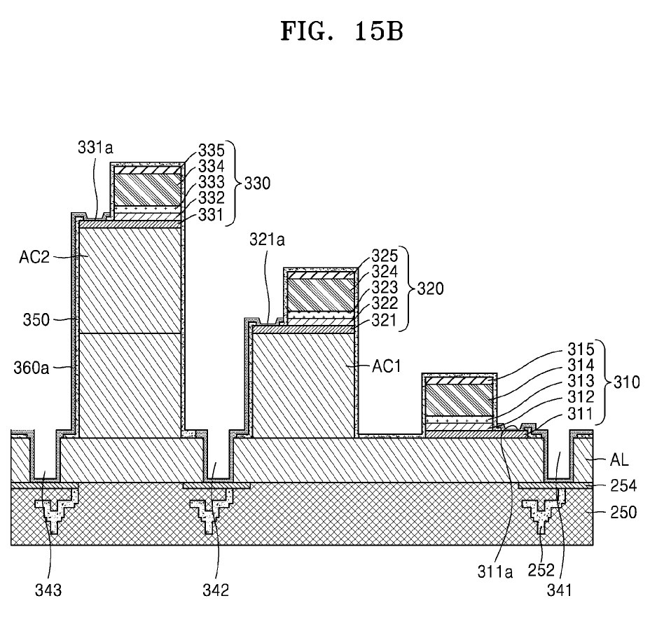

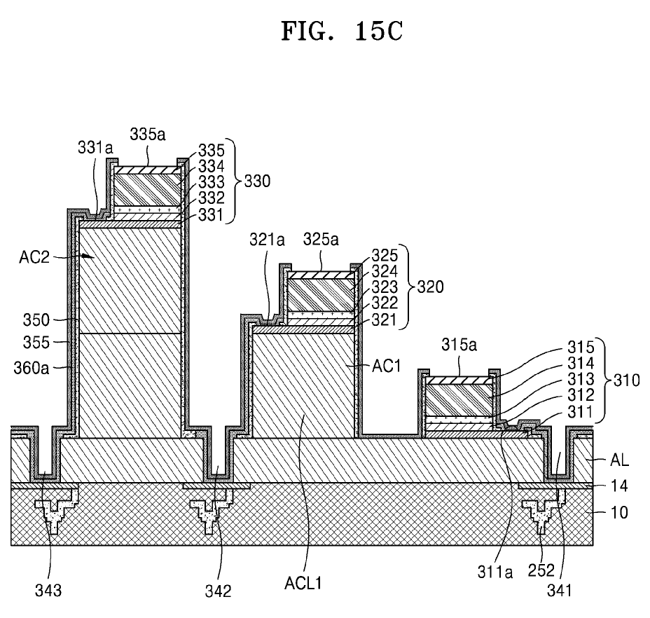

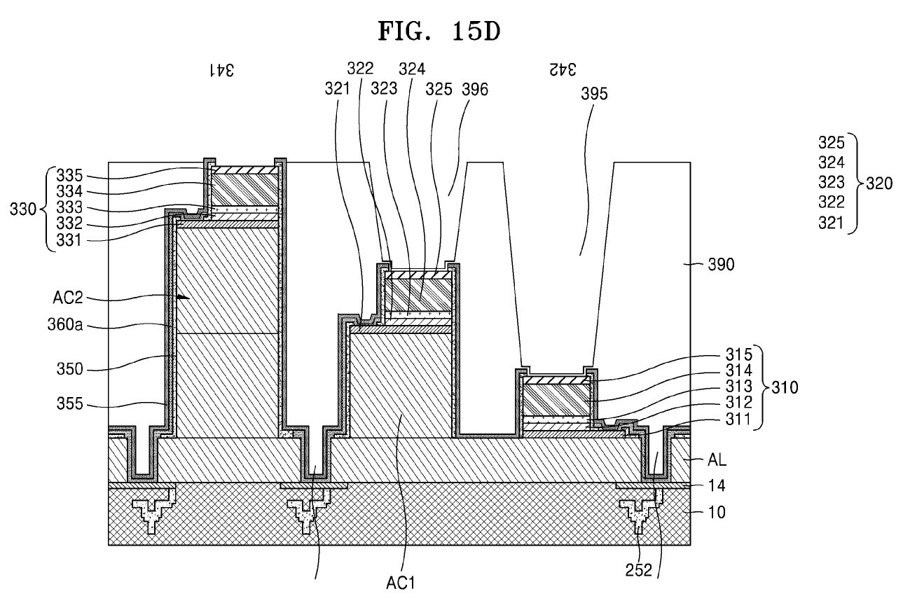

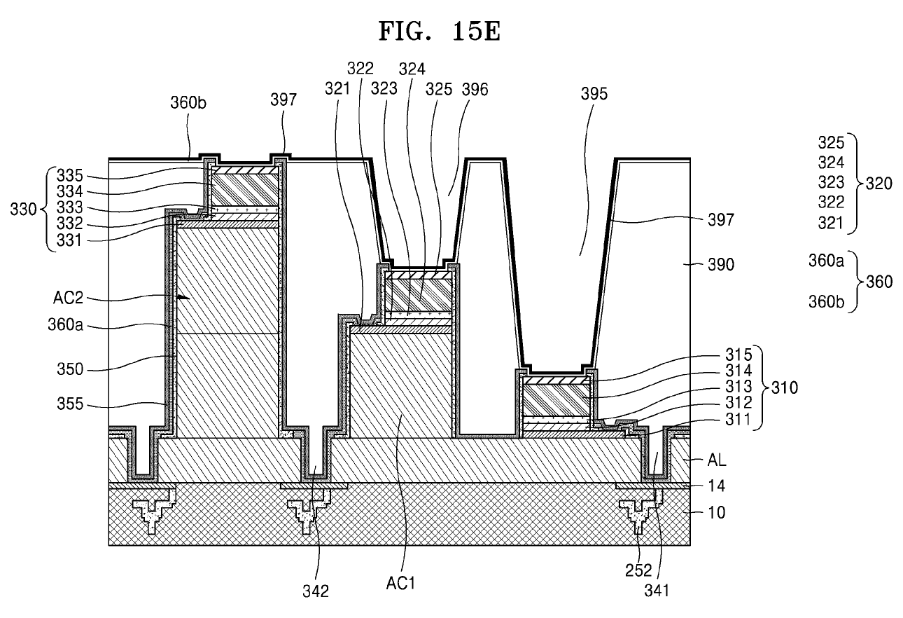

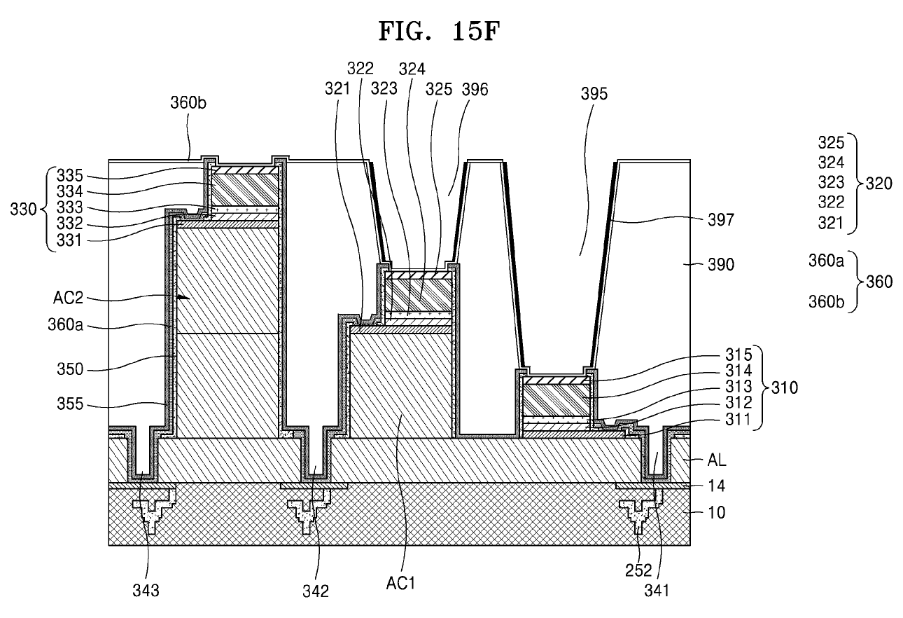

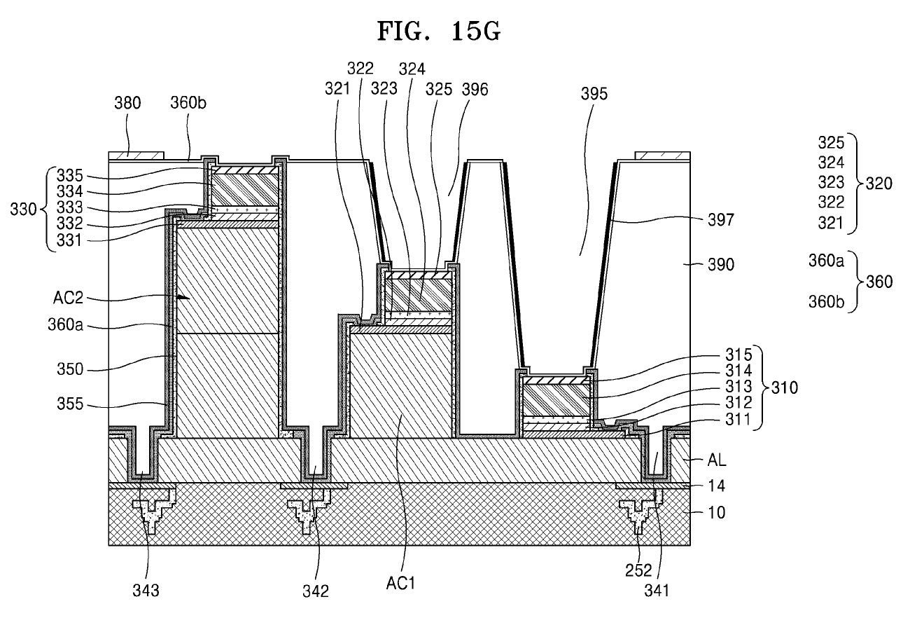

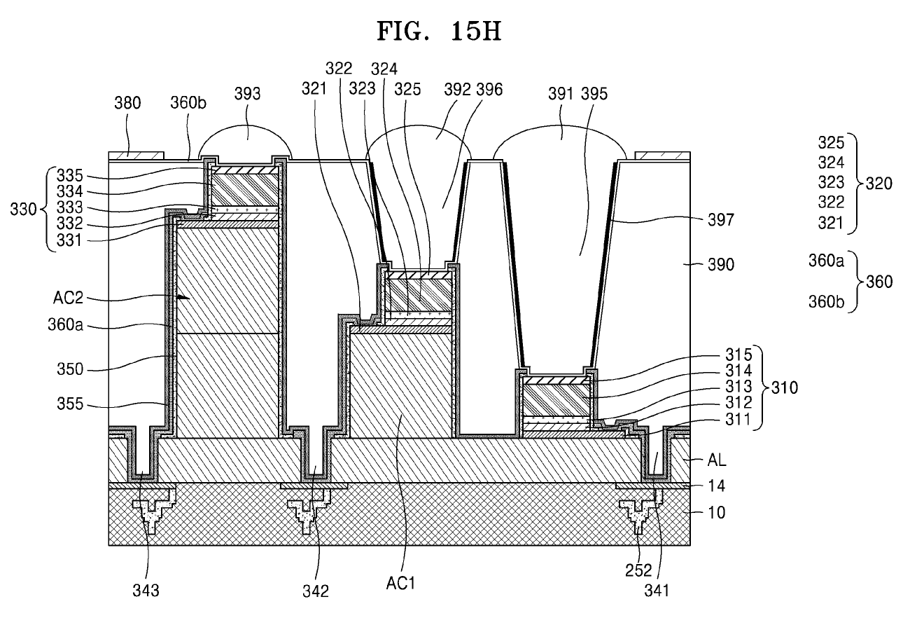

FIGS. 15A to 15H are diagrams illustrating a method of forming an electrode connection structure of a micro light emitting display device according to one or more embodiments.

Referring to FIG. 15A, a charge blocking layer 350 may be deposited on the entire structure shown in FIG. 11G. The charge blocking layer 350 may include AlN, AlOₓ, SiO₂, or a combination thereof. In addition, the charge blocking layer 350 may be patterned to expose some upper regions of the bonding layer AL, the open surface 311a of the first electrode 311, the open surface 321a of the third electrode 321, the open surface 331a of the fifth electrode 331, and the top surfaces 315a, 325a, and 335a of the second electrode 315, the fourth electrode 325, and the sixth electrode 335. In addition, a first groove 341, a second groove 342, and a third groove 343 may be formed by etching the bonding layer AL. The first groove 341, the second groove 342 and the third groove 343 may be formed through the bonding layer AL so that the electrode pad 254 is exposed.

The charge blocking layer 350 may be formed on the side surfaces of the first light emitting device 310, the second light emitting device 320, and the third light emitting device 330. The charge blocking layer 350 formed on the side surface of the first light emitting device 310 may prevent a short circuit between the first semiconductor layer 312 and the second semiconductor layer 314 of the first light emitting device 310. The charge blocking layer 350 formed on the side surface of the second light emitting device 320 may prevent a short circuit between the third semiconductor layer 322 and the fourth semiconductor layer 324 of the second light emitting device 320. The charge blocking layer 350 formed on the side surface of the third light emitting device 330 may prevent a short circuit between the fifth semiconductor layer 332 and the sixth semiconductor layer 334 of the third light emitting device 330.

Referring to FIG. 15B, a first conductive layer 360a may be deposited on the charge blocking layer 350. The first conductive layer 360a may be deposited and patterned to cover the entire structure to form a wiring structure.

The first conductive layer 360a may be deposited in the first groove 341, the second groove 342, and the third groove 343 and connected to the electrode pads 254. In addition, the first conductive layer 360a may extend to the open surface 331a of the fifth electrode 331 along one sidewall of the second bonding pillar AC2. The first conductive layer 360a may extend to the open surface 321a of the third electrode 321 along one sidewall of the first bonding pillar AC1. The first conductive layer 360a may extend to the open surface 311a of the first electrode 311.

Referring to FIG. 15C, a second charge blocking layer 355 may be deposited on the structure shown in FIG. 15B. The second charge blocking layer 355 may include AlN, AlOₓ, SiO₂, or a combination thereof. In addition, the second charge blocking layer 355 may be patterned to expose the respective top surfaces of the first light emitting device 310, the second light emitting device 320, and the third light emitting device 330. The second charge blocking layer 355 may expose the respective top surfaces 315a, 325a, and 335a of the second electrode 315, the fourth electrode 325, and the sixth electrode 335.

Referring to FIG. 15D, a planarization layer 390 may be formed to at least partially cover the first light emitting device 310, the second light emitting device 320, and the third light emitting device 330. The planarization layer 390 may flatten the first light emitting device 310, the second light emitting device 320, and the third light emitting device 330 having different heights. The planarization layer 390 may include, for example, an acrylic polymer. However, the planarization layer 390 is not limited thereto. The planarization layer 390 may be provided up to the height of the top surface of the third light emitting device 330. For example, the top surface of the planarization layer 390 and the top surface of the third light emitting device 330 may be at the same height. However, the height of the planarization layer 390 is not limited thereto.

A first hole 395 exposing the second electrode 315 of the first light emitting device 310 and a second hole 396 exposing the fourth electrode 325 of the second light emitting device 320 may be etched in the planarization layer 390. The first hole 395 may be provided in the planarization layer 390 to expose the top surface of the first light emitting device 310, and a second hole 396 may be provided to expose the top surface of the second light emitting device 320. A separate hole may not be provided in the upper portion of the third light emitting device 330. However, it is possible to have a hole in the upper portion of the third light emitting device 330.

Referring to FIG. 15E, a second conductive layer 360b may be formed to contact the second electrode 315 of the first light emitting device 310 exposed through the first hole 395 and the fourth electrode 325 of the second light emitting device 320 exposed through the second hole 396. The second conductive layer 360b may be deposited to cover the planarization layer 390 and the exposed top surface of the first light emitting device 310, the exposed top surface of the second light emitting device 320, and the exposed top surface of the third light emitting device 330. A reflective layer 397 may be deposited on the second conductive layer 360b.

The second conductive layer 360b may connect the top surface of the first light emitting device 310, the top surface of the second light emitting device 320, and the top surface of the third light emitting device 330, with each other. The second conductive layer 360b may electrically connect the second electrode 315 of the first light emitting device 310, the fourth electrode 325 of the second light emitting device 320, and the sixth electrode 335 of the third light emitting device 330, with each other.

The second conductive layer 360b may include a conductive material. For example, the second conductive layer 360b may include a transparent electrode material. The second conductive layer 360b may include a transparent electrode material. The second conductive layer 360b may include, for example, ITO, ZnO, IZO, IGZO, or the like. The second conductive layer 360b may include the same material as the second electrode 315. However, the material of the second conductive layer 360b is not limited thereto.

The reflective layer 397 may include a reflective material to reflect light emitted from the corresponding light emitting device. For example, the reflective layer 397 may include Al or Ag.

Referring to FIG. 15F, the reflective layer 397 may be etched. The reflective layer 397 may be etched to be arranged on the side surfaces of the first hole 395 and the second hole 396. The reflective layer 397 arranged on the side surfaces of the first hole 395 and the second hole 396 may reflect light emitted from the first light emitting device 310 and the second light emitting device 320. The reflective layer 397 may be removed so that the reflective layer 397 does not remain on the top surface of the planarization layer 390. The second conductive layer 360b may be exposed on the top surface of the planarization layer 390 from which the reflective layer 397 has been removed.

Referring to FIG. 15G, a bus electrode 380 may be arranged on the second conductive layer 360b.

The bus electrode 380 may include a material having high conductivity. For example, the bus electrode 380 may include at least one of aluminum, chromium, and copper. The bus electrode 380 may include a material having a higher conductivity than a material of the second conductive layer 360b. For example, when the material of the second conductive layer 360b is ITO, the bus electrode 380 may include at least one of aluminum, chromium, and copper. The bus electrode 380 may be a common electrode.

The bus electrode 380 may be arranged in a lattice shape on a plane. The bus electrode 380 may be arranged at an edge of the pixel.

Referring to FIG. 15H, a lens may be formed on each of the first light emitting device 310, the second light emitting device 320, and the third light emitting device 330.

A first lens 391 may be provided in the first hole 395, and a second lens 392 may be provided in the second hole 396. The first lens 391 may fill the first hole 395 and an upper surface thereof may have a convex shape. That is, the first lens 391 may be formed as a single body from the upper portion of the first light emitting device 310 to the convex portion. Here, the first lens 391 is provided to fill the first hole 395, but it is also possible to fill the first hole 395 with another layer and have the first lens 391 on top of the first hole 395. That is, the first lens 391 may include a portion of filling the first hole 395 and a convex portion, which are formed as separate bodies. The first lens 391 may be arranged to have the same central axis as the central axis of the first active layer 313.

The second lens 392 may fill the second hole 396 and an upper surface thereof may have a convex shape. A third lens 393 may be provided above the third light emitting device 330. That is, the second lens 392 may be formed as a single body from the upper portion of the second light emitting device 320 to the convex portion. Alternatively, as described with respect to the first lens 391, the portion of the second lens 392 filling the second hole 396 and the convex portion may be formed as separate bodies. The second lens 392 may be arranged to have the same central axis as the central axis of the second active layer 323.

The third lens 393 may be provided above the third light emitting device 330 and may have a convex shape. The third lens 393 may be provided directly above the third light emitting device 330 without a separate hole portion. However, it is also possible to have a structure in which the third lens 393 is provided in the hole portion.

In the micro light emitting display device, convex portions of the first lens 391, the second lens 392, and the third lens 393 may be arranged at the same height. Thus, the light emitted from the first light emitting device 310, the second light emitting device 320, and the third light emitting device 330 which are located at different heights may be effectively condensed.

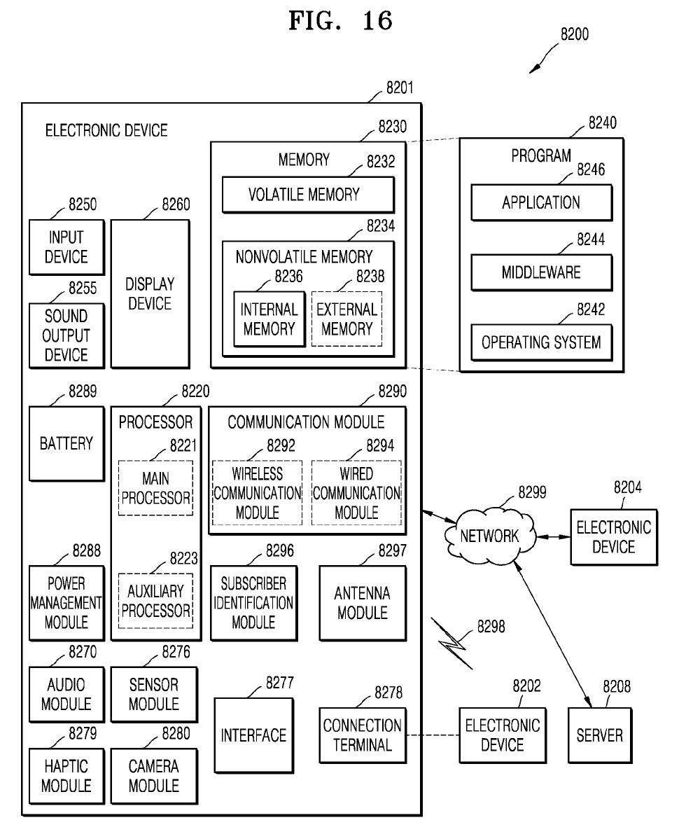

FIG. 16 is a block diagram of an electronic device including a display device, according to one or more embodiments. Referring to FIG. 16, an electronic device 8201 may be provided in a network environment 8200. In the network environment 8200, the electronic device 8201 may communicate with another electronic device 8202 through the first network 8298 (a short-range wireless communication network, etc.), or with another electronic device 8204 and/or the server 8208 through the second network 8299 (a long-distance wireless communication network, etc.). The electronic device 8201 may communicate with the electronic device 8204 through the server 8208. The electronic device 8201 may include a processor 8220, a memory 8230, an input device 8250, an sound output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of these components may be omitted from the electronic device 8201 or other components may be added to the electronic device 8201. Some of these components may be implemented as one integrated circuit. For example, the sensor module 8276 (fingerprint sensor, iris sensor, illumination sensor, etc.) may be implemented by being embedded in the display device 8260 (display, etc.).

The processor 8220 may execute software (program 8240 or the like) to control one or a plurality of other components (hardware and software components, or the like) of the electronic device 8201 connected to the processor 8220, and may perform processing or operations of various data. As part of data processing or operation, the processor 8220 may load commands and/or data received from other components (sensor modules 8276, communication modules (8290, etc.), process commands and/or data stored in volatile memory 8232, and store the result data in nonvolatile memory 8234. The nonvolatile memory 8234 may include an internal memory 8236 and an external memory 8238. The processor 8220 may include a main processor 8221 (a central processing unit, an application processor, etc.) and an auxiliary processor 8223 (a graphics processing unit, an image signal processor, a sensor hub processor, a communication processor, etc.) that may be operated independently of or together with the main processor 8221. The auxiliary processor 8223 may use less power than the main processor 8221 and perform a specialized function.

The auxiliary processor 8223 may control functions and /or states related to some (the display device 8260, sensor module 8210, communication module 8290, etc.) of the components of the electronic device 8201, in place of the main processor 8221 while the main processor 8221 is in an inactive state (slip state), or together with the main processor 8221 while the main processor 8221 is in an active state (application execution state). The auxiliary processor 8223 (image signal processor, communication processor, etc.) may be implemented as part of other functionally related components (camera module 8280, communication module 8290, etc.).

The memory 8230 may store various data required by components (processor 8220 and sensor module 8276) of the electronic device 8201. The data may include, for example, input data and/or output data for software (program 8240 or the like) and related commands. The memory 8230 may include a volatile memory 8232 and/or a nonvolatile memory 8234.

The program 8240 may be stored in the memory 8230 as software, and may include an operating system 8242, middleware 8244, and/or an application 8246.

The input device 8250 may receive commands and/or data to be used in components (processor 8220, etc.) of the electronic device 8201 from the outside (user, etc.) of the electronic device 8201. The input device 8250 may include a remote controller, a microphone, a mouse, a keyboard, and/or a digital pen (such as a stylus pen, etc.).

The sound output device 8255 may output the sound signal to the outside of the electronic device 8201. The sound output device 8255 may include a speaker and/or a receiver. Speakers may be used for general purposes such as multimedia playback or recording playback, and receivers may be used to receive incoming calls. The receiver may be coupled as part of a speaker or may be implemented as an independent separate device.

The display device 8260 may visually provide information to the outside of the electronic device 8201. The display device 8260 may include a display, a hologram device, or a projector and a control circuit for controlling the corresponding devices. The display device 8260 may include a display device according to one or more embodiments. The display device 8260 may include a touch circuitry configured to sense a touch, and/or a sensor circuit (a pressure sensor, etc.) configured to measure an intensity of a force generated by the touch.

The audio module 8270 may convert sound into an electrical signal or conversely convert the electrical signal into sound. The audio module 8270 may acquire sound through the input device 8250 or output sound through the sound output device 8255 and/or a speaker and/or a headphone of another electronic device (e.g., electronic device 8202, etc.) directly or wirelessly connected to the electronic device 8201.

The sensor module 8276 may detect an operating state (power, temperature, etc.) or an external environmental state (user state, etc.) of the electronic device 8201 and generate an electrical signal and/or a data value corresponding to the sensed state. The sensor module 8276 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface 8277 may support one or more designated protocols that may be used for electronic device 8201 to be directly or wirelessly connected to another electronic device (e.g., electronic device 8202, etc.). The interface 8277 may include a high definition multimedia interface (HDMI), a universal serial bus (USB) interface, an SD card interface, and/or an audio interface.

The connection terminal 8278 may include a connector through which the electronic device 8201 may be physically connected to another electronic device (e.g., electronic device 8202, etc.). The connection terminal 8278 may include an HDMI connector, a USB connector, an SD card connector, and/or an audio connector (such as a headphone connector, etc.).

The haptic module 8279 may convert an electrical signal to a mechanical stimulus (vibration, motion, etc.) or an electrical stimulus that a user can recognize through a tactile or motion sensation. The haptic module 8279 may include a motor, a piezoelectric element, and/or an electrical stimulus.

The camera module 8280 may capture a still image and a moving image. The camera module 8280 may include a lens assembly including one or more lenses, image sensors, image signal processors, and/or flashes. The lens assembly included in the camera module 8280 may concentrate light emitted from an object to be photographed.

The power management module 8288 may manage power supplied to the electronic device 8201. The power management module 8288 may be implemented as part of a power management integrated circuit (PMIC).

The battery 8289 may supply power to components of the electronic device 8201. The battery 8289 may include a non-rechargeable primary battery, a rechargeable secondary battery, and/or a fuel cell.

The communication module 8290 may establish a direct (wired) communication channel and/or wireless communication channel between the electronic device 8201 and another electronic device (the electronic device 8202, the electronic device 8204, the server 8208, etc.), and support communication execution through the established communication channel. The communication module 8290 may include one or more communication processors that operate independently of the processor 8220 (application processor, etc.) and support direct communication and/or wireless communication. The communication module 8290 may include a wireless communication module 8292 (a cellular communication module, a short-range wireless communication module, a Global Navigation Satellite System (GNSS), etc.) communication module, and/or a wired communication module 8294 (a local area network (LAN) communication module, a power line communication module, etc.). A corresponding communication module of these communication modules may communicate with other electronic devices through a first network 8298 (a short-range communication network such as Bluetooth, WiFi Direct, or infrared data association (IrDA)), or a second network 8299 (a long-range communication network such as a cellular network, Internet, or computer network (LAN, wide area network (WAN), etc.)). These various types of communication modules may be integrated into a single component (such as a single chip, etc.), or may be implemented as a plurality of separate components (multiple chips). The wireless communication module 8292 may identify and authenticate the electronic device 8201 in a communication network such as a first network 8298 and/or a second network 8299 using subscriber information (such as an international mobile subscriber identifier (IMSI) stored in the subscriber identification module 8296.

The antenna module 8297 may transmit a signal and/or power to the outside (such as another electronic device, etc.) or receive the signal and/or power from the outside. The antenna may include a radiator formed of a conductive pattern formed on the substrate (printed circuit board (PCB), etc.). The antenna module 8297 may include one or a plurality of antennas. When a plurality of antennas are included, an antenna suitable for a communication scheme used in a communication network such as a first network 8298 and/or a second network 8299 may be selected from among the plurality of antennas by the communication module 8290. A signal and/or power may be transmitted or received between the communication module 8290 and another electronic device through the selected antenna. Other components (radio frequency integrated circuit (RFIC), etc.) in addition to the antenna may be included as a part of the antenna module 8297.

Some of the components are connected to each other and may exchange signals (commands, data, etc.) via a communication scheme (bus, General Purpose Input and Output (GPIO), Serial Peripheral Interface (SPI), Mobile Industry Processor Interface (MIPI), etc.) and can interchange signals (commands, data, etc.) between peripherals.

The command or data may be transmitted or received between the electronic device 8201 and the external electronic device 8204 through the server 8208 connected to the second network 8299. Other electronic devices 8202 and 8204 may be the same or different types of devices as the electronic device 8201. All or some of the operations executed in the electronic device 8201 may be executed in one or more of the other electronic devices 8202, 8204, and 8208. For example, when the electronic device 8201 needs to perform a function or service, it may request one or more other electronic devices to perform part or all of the function or service instead of executing the function or service on its own. One or more other electronic devices receiving the request may execute an additional function or service related to the request and transmit a result of the execution to the electronic device 8201. To this end, cloud computing, distributed computing, and/or client-server computing technology may be used.

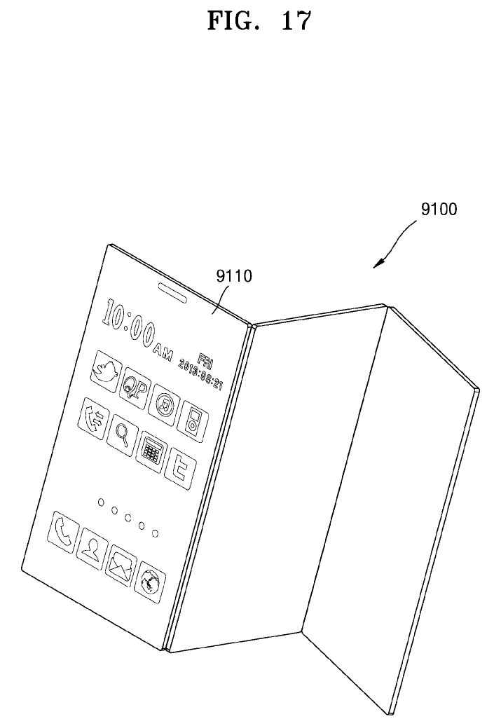

FIG. 17 is a diagram illustrating an example of applying an electronic device to a mobile device according to one or more embodiments. A mobile device 9100 may include a display device 9110, and the display device 9110 may include display devices according to one or more embodiments. The display device 9110 may have a foldable structure, for example, a multi-foldable structure.

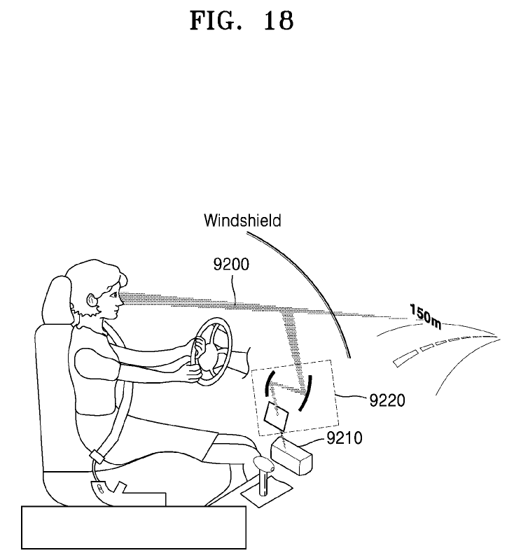

FIG. 18 is a diagram illustrating an example of applying a display device to a vehicle according to one or more embodiments. A display device may be a head-up display device 9200 for a vehicle, and may include a display 9210 provided in one area of the vehicle, and an optical path change member 9220 that converts an optical path so that the driver may see the image generated by the display 9210.

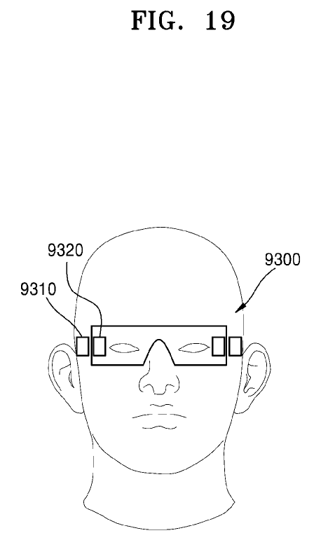

FIG. 19 is a diagram illustrating an example of applying a display device to augmented reality glasses or virtual reality glasses according to one or more embodiments. The augmented reality glasses 9300 each may include a projection system 9310 forming an image and an element 9320 guiding the image from the projection system 9310 to enter the user’s eye. The projection system 9310 may include a display device according to one or more embodiments.

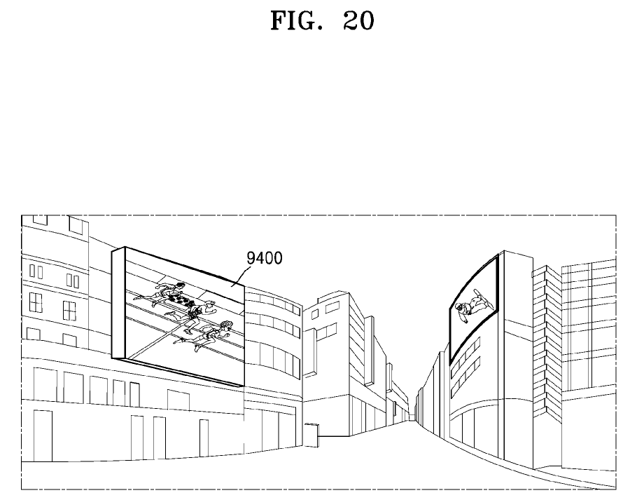

FIG. 20 is a diagram illustrating an example of applying a display device to a large signage according to one or more embodiments. A signage 9400 may be used for outdoor advertisements using a digital information display and may control advertisement content, etc., through a communication network. The signage 9400 may be implemented through, for example, the electronic device described with reference to FIG. 16.

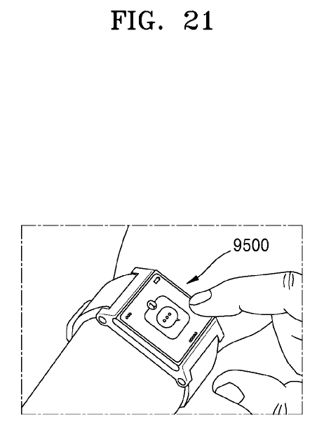

FIG. 21 is a diagram illustrating an example of applying a display device to a wearable display according to one or more embodiments. The wearable display 9500 may include a display device according to one or more embodiments, and may be implemented through the electronic device described with reference to FIG. 16.

The display device according to one or more embodiments may be applied to various products such as a rollable television (TV) and a stretchable display.

One or more embodiments may implement a display device that displays a high-resolution color image using a micro light emitting device.

The display device according to one or more embodiments may simplify the display device by using a micro light emitting structure that directly displays a green color or a red color without a process of converting blue light into green light or red light.

In the method of manufacturing a display device according to one or more embodiments, a display device that transfers an epitaxial structure to display a color image may be manufactured.

Each of one or more embodiments provided in the above description is not excluded from being associated with one or more features of another example or another embodiment also provided herein or not provided herein but consistent with the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A micro light emitting display device comprising:
a backplane substrate comprising at least one driving device;
a bonding layer on the backplane substrate;
a first bonding pillar extending in a first direction that is perpendicular to an upper surface of the backplane substrate; and
a first light emitting device and a second light emitting device spaced apart from each other in a second direction intersecting the first direction;
wherein the first light emitting device is on the bonding layer, and
wherein the second light emitting device is on the first bonding pillar such that the second light emitting device is positioned at a height in the first direction that is different from a height at which the first light emitting device is positioned in the first direction.

2. The micro light emitting display device of claim 1, wherein the first bonding pillar is between the bonding layer and the second light emitting device and protrudes from the bonding layer toward the second light emitting device.

3. The micro light emitting display device of claim 1, wherein the first bonding pillar comprises a polymer-based material.

4. The micro light emitting display device of claim 1, wherein the first bonding pillar comprises a material that is the same as a material of the bonding layer.

5. The micro light emitting display device of claim 1, wherein the first light emitting device comprises a first electrode, a first semiconductor layer, a first active layer configured to emit light of a first wavelength, a second semiconductor layer, and a second electrode, which are stacked in order in the first direction,
wherein the second light emitting device comprises a third electrode, a third semiconductor layer, a second active layer configured to emit light having a second wavelength different from the first wavelength, a fourth semiconductor layer, and a fourth electrode, which are stacked in order in the first direction,
wherein, in the second direction, the first electrode has a width that is greater than a width of the first semiconductor layer,
wherein the first electrode comprises a first open surface extending from a side of the first light emitting device and connected to at least one driving device of the at least one driving device,
wherein, in the second direction, the third electrode has a width that is greater than a width of the third semiconductor layer, and
wherein the third electrode comprises a second open surface extending from a side of the second light emitting device and connected to at least one driving device of the at least one driving device.

6. The micro light emitting display device of claim 5, wherein, in the second direction, the first bonding pillar has a width that is greater than a width of the second active layer of the second light emitting device.

7. The micro light emitting display device of claim 5, wherein, in the second direction, the first bonding pillar has a width that is substantially the same as the width of the third electrode.

8. The micro light emitting display device of claim 5, further comprising a first conductive layer configured to connect the at least one driving device to at least one of the first open surface and the second open surface.

9. The micro light emitting display device of claim 8, further comprising a planarization layer covering the first conductive layer,
wherein a surface of the first light emitting device and a surface of the second light emitting device are exposed through the planarization layer.

10. The micro light emitting display device of claim 9, further comprising a second conductive layer contacting the surface of the first light emitting device and the surface of the second light emitting device which are exposed through the planarization layer.

11. The micro light emitting display device of claim 10, further comprising:
a first lens above the first light emitting device and having a convex upper portion; and
a second lens above the second light emitting device and having a convex upper portion.

12. The micro light emitting display device of claim 9, wherein the planarization layer comprises a first hole exposing the surface of the first light emitting device, and
wherein the micro light emitting display device further comprises a reflective layer on a side surface of the first hole.

13. The micro light emitting display device of claim 1, wherein a surface of the first light emitting device and a surface of the second light emitting device each comprise an uneven structure.

14. The micro light emitting display device of claim 1, further comprising:
a second bonding pillar extending in the first direction to a height that is different from a height of the first bonding pillar; and
a third light emitting device on the second bonding pillar and spaced apart from the second light emitting device in the second direction such that the third light emitting device is positioned at a height in the first direction that is different from the height of the first light emitting device in the first direction and the height of the second light emitting device in the first direction.

15. A method of manufacturing a micro light emitting display device, the method comprising:
providing a first bonding layer on a backplane substrate;
forming a first light emitting device on the first bonding layer;
providing a second bonding layer that covers the first light emitting device and the first bonding layer;
forming a second light emitting device on the second bonding layer; and
etching the second bonding layer such that a first bonding pillar is formed below the second light emitting device in a first direction that is perpendicular to an upper surface of the backplane substrate.

16. The method of claim 15, wherein the forming of the first light emitting device comprises:
forming a first epitaxial structure by providing a second epitaxial semiconductor layer, a first epitaxial active layer, a first epitaxial semiconductor layer, and a first epitaxial electrode in order on a first epitaxial substrate;
inverting the first epitaxial structure and providing the inverted first epitaxial structure on the first bonding layer;
removing the first epitaxial substrate of the first epitaxial structure;
forming a second epitaxial electrode on the first epitaxial structure; and
etching the first epitaxial structure such that a width of the first light emitting device is on the upper surface of the first bonding layer, and
wherein the forming of the second light emitting device comprises:
forming a second epitaxial structure by providing a third epitaxial electrode on the second bonding layer, a third epitaxial semiconductor layer on the third epitaxial electrode, a second epitaxial active layer on the third epitaxial semiconductor layer, and a fourth epitaxial semiconductor layer on the second epitaxial active layer;
forming a fourth epitaxial electrode on the second epitaxial structure; and
etching the second epitaxial structure such that a width of the second light emitting device is less than a width of the second bonding layer.

17. The method of claim 16, wherein the backplane substrate comprises at least one driving device;
wherein the first light emitting device comprises a first electrode, a first semiconductor layer, a first active layer configured to emit light of a first wavelength, a second semiconductor layer, and a second electrode, which are stacked in order on the first bonding layer,
wherein the second light emitting device comprises a third electrode, a third semiconductor layer, a second active layer configured to emit light having a second wavelength different from the first wavelength, a fourth semiconductor layer, and a fourth electrode, which are stacked in order on the second bonding layer;
wherein the first electrode has a width that is greater than a width of the first semiconductor layer and comprises a first open surface extending from a side of the first light emitting device;
wherein the third electrode has a width that is greater than a width of the third semiconductor layer and comprises a second open surface extending from a side of the second light emitting device, and
wherein the method further comprises forming a first conductive layer respectively connecting driving devices of the at least one driving device to the first electrode and the second electrode.

18. The method of claim 17, further comprising:
forming a planarization layer covering the first conductive layer;
forming a first hole in the planarization layer exposing the second electrode of the first light emitting device;
forming a second hole in the planarization layer exposing the fourth electrode of the second light emitting device; and
forming a second conductive layer that contacts the second electrode exposed through the first hole and the fourth electrode exposed through the second hole.

19. The method of claim 18, further comprising:
forming a first lens filling the first hole and having a shape with a convex upper portion; and
forming a second lens filling the second hole and having a shape with a convex upper portion.

20. The method of claim 19, further comprising, prior to forming the first lens, forming a reflective layer on a side surface of the first hole.
